(19) United States
(12) Patent Application Publication
(10) Pub. No.: US 2024/0060168 A1
(43) Pub. Date: Feb. 22, 2024

(54) METHOD OF MANUFACTURING MASK, MASK AND METHOD OF MANUFACTURING MASK APPARATUS

(71) Applicant: DAI NIPPON PRINTING CO., LTD., Tokyo (JP)

(72) Inventors: Hideyuki OKAMOTO, Tokyo (JP); Chikao IKENAGA, Tokyo (JP)

(73) Assignee: DAI NIPPON PRINTING CO., LTD., Tokyo (JP)

(21) Appl. No.: 18/339,350

(22) Filed: Jun. 22, 2023

(30) Foreign Application Priority Data
Jun. 27, 2022 (JP) 2022-103061

(51) Int. Cl. C23C 14/04; C23C 14/24; G03F 9/00; G03F 1/50

(52) U.S. Cl. CPC C23C 14/042; C23C 14/24; G03F 9/7096; G03F 1/50

(57) ABSTRACT

A mask may include a first portion including at least one first through-hole group, and a second portion including at least one second through-hole group located next to the first through-hole group in a first direction. A method of manufacturing the mask may include: a step of preparing a laminated body that includes an original base material and a resist layer; a first exposure process of exposing the resist layer corresponding to the first portion by using a first exposure mask; a second exposure process of exposing the resist layer corresponding to the second portion by using a second exposure mask; a process of developing the resist layer corresponding to the first portion and the resist layer corresponding to the second portion; and a process of etching the original base material through the resist layer corresponding to the first portion and the resist layer corresponding to the second portion.

### CROSS-REFERENCE TO RELATED APPLICATIONS

The present application contains subject matter related to Japanese Patent Application No. 2022-103061 filed in the Japan Patent Office on Jun. 27, 2022, the entire contents of which are incorporated herein by reference.

### BACKGROUND

### 1. Field

Embodiments of the present disclosure relate to a method of manufacturing a mask, a mask, and a method of manufacturing a mask apparatus.

### 2. Description of the Related Art

Organic devices such as organic EL display devices have been attracting attention. As a method of forming an element such as an organic device, a method of putting a material of the element onto a substrate by vapor deposition is known. For example, a substrate on which first electrodes are formed in a pattern corresponding to elements is prepared. Next, an organic material is put onto the first electrodes via through holes of the mask, thereby forming an organic layer on the first electrodes. Next, second electrodes are formed on the organic layer.

As a method of manufacturing a mask, a method of forming through holes by etching a base material such as a metal plate is known. The manufacturing method includes a step of exposing a resist layer on a base material by using an exposure mask and a step of etching the base material through the resist layer having been exposed and developed. Related art is disclosed in Japanese Patent No. 3539597.

### SUMMARY

One of conceivable approaches for reducing the manufacturing cost of an organic device is to increase the size of a substrate. As the size of a substrate increases, so does the size of a mask, resulting in larger manufacturing facilities for mask production. For example, in order to manufacture a mask corresponding to an eighth-generation substrate, an exposure mask corresponding to the eighth-generation substrate is needed. However, making the exposure mask larger requires a heavy investment.

Embodiments of the present disclosure provide a method of manufacturing a mask that can provide an effective solution to this issue.

In a method of manufacturing a mask according to an embodiment of the present disclosure, the mask may include a first portion including at least one first through-hole group, and a second portion including at least one second through-hole group located next to the first through-hole group in a first direction. The manufacturing method may include: a step of preparing a laminated body that includes an original base material and a resist layer; a first exposure process of exposing the resist layer corresponding to the first portion by using a first exposure mask; a second exposure process of exposing the resist layer corresponding to the second portion by using a second exposure mask; a process of developing the resist layer corresponding to the first portion and the resist layer corresponding to the second portion; and a process of etching the original base material through the resist layer corresponding to the first portion and the resist layer corresponding to the second portion. The first exposure mask may include a first surface first exposure mask, through which the resist layer located on a first surface of the original base material is exposed, and a second surface first exposure mask, through which the resist layer located on a second surface of the original base material is exposed. In the first exposure process, the resist layer located on the first surface may be exposed using the first surface first exposure mask, and the resist layer located on the second surface may be exposed using the second surface first exposure mask. The second exposure mask may include a first surface second exposure mask, through which the resist layer located on the first surface is exposed, and a second surface second exposure mask, through which the resist layer located on the second surface is exposed. In the second exposure process, the resist layer located on the first surface may be exposed using the first surface second exposure mask, and the resist layer located on the second surface may be exposed using the second surface second exposure mask. A peripheral edge of the first portion and the first through-hole group may be formed through the original base material by etching through the resist layer corresponding to the first portion. A peripheral edge of the second portion and the second through-hole group may be formed through the original base material by etching through the resist layer corresponding to the second portion.

An embodiment of the present disclosure makes it possible to reduce an investment for increasing the size of a mask.

### BRIEF DESCRIPTION OF DRAWINGS

FIG. 1 is a cross-sectional view of an example of an organic device.

FIG. 2 is a plan view of an example of an organic device group.

FIG. 3 is a cross-sectional view of an example of a vapor deposition apparatus.

FIG. 4 is a plan view of an example of a mask apparatus.

FIG. 5 is a plan view of an example of a mask.

FIG. 6 is a plan view of an example of a first end of the mask.

FIG. 7A is a plan view of an example of a first middle portion and a second middle portion.

FIG. 7B is a diagram illustrating an example of a relationship between a first array direction and a second array direction.

FIG. 7C is a diagram illustrating an example of a relationship between the first array direction and the second array direction.

FIG. 8 is a plan view of an example of the first middle portion and the second middle portion.

FIG. 9 is a plan view of an example of the first middle portion and the second middle portion.

FIG. 10 is a cross-sectional view, viewed in a direction A-A, of the mask illustrated in FIG. 5.

FIG. 11 is a cross-sectional view of a base material used for manufacturing a mask.

FIG. 12A is a plan view of an example of a process of exposing a resist layer by using a first exposure mask.

FIG. 12B is a cross-sectional view, viewed in a direction B-B, of the base material illustrated in FIG. 12A.

FIG. 13A is a plan view of an example of the resist layer exposed by using the first exposure mask.

FIG. 13B is a cross-sectional view, viewed in a direction C-C, of the base material illustrated in FIG. 13A.

FIG. 14A is a plan view of an example of a process of exposing a resist layer by using a second exposure mask.

FIG. 14B is a cross-sectional view, viewed in a direction D-D, of the base material illustrated in FIG. 14A.

FIG. 15A is a plan view of an example of the resist layer exposed by using the second exposure mask.

FIG. 15B is a cross-sectional view, viewed in a direction E-E, of the base material illustrated in FIG. 15A.

FIG. 16 is a cross-sectional view of an example of an etched base material.

FIG. 17A is a plan view of an example of a mask formed in the base material.

FIG. 17B is a cross-sectional view, viewed in a direction F-F, of the base material illustrated in FIG. 17A.

FIG. 18 is a plan view of an example of an alignment step in which the position of the mask in relation to a mask support is determined.

FIG. 19 is a plan view of an example of the mask to which tension is applied.

FIG. 20 is a plan view of an example of an adjustment step.

FIG. 21 is a plan view of an example of a shift step.

FIG. 22A is a plan view of an example of a mask according to Example 1.

FIG. 22B is a graph showing deviation distances of through holes of the mask according to Example 1.

FIG. 23 is a graph showing deviation distances of the mask according to Example 1 in a state in which tension is applied thereto.

FIG. 24 is a graph showing deviation distances of the through holes of the mask according to Example 1 in a state after the execution of the adjustment step.

FIG. 25 is a graph showing deviation distances of the through holes of the mask according to Example 1 in a state after the execution of the shift step.

FIG. 26 is a table showing the maximum value of deviation distances according to Examples 1 to 5.

### DETAILED DESCRIPTION

In this specification and the drawings, terms that mean matters defining a base of a certain structure, for example, “substrate”, “base material”, “plate”, “sheet”, “film”, etc., are not distinguished from one another based on differences in nominal designation only, unless otherwise specified.

In this specification and the drawings, terms that specify shapes and geometric conditions, and the extent thereof, for example, terms such as “parallel” and “orthogonal”, and values of length, angle, and the like, shall be construed each to encompass a range in which a similar function may be expected, without being bound to its strict sense, unless otherwise specified.

In this specification and the drawings, a case where a certain component such as a certain member or a certain area is “on (on top of)”, “beneath”, “above”, “below”, “over”, or “under” another component such as another member or another area encompasses a case where said certain component is directly in contact with said another component, unless otherwise specified. In addition, a case where still another component is interposed between said certain component and said another component, that is, a case of indirect contact, is also encompassed therein. Moreover, the words “on (on top of)”, “above”, and “over”, or “beneath”, “below”, and “under” may be construed with upside-down inversion, unless otherwise specified.

In this specification and the drawings, the same or similar reference signs may be assigned to the same portions or portions having similar functions, and duplicative explanation may be omitted, unless otherwise specified. Dimensional ratios in the drawings may be made different from actual ratios for easier understanding, or a part of a configuration may be omitted from the drawings.

In this specification and the drawings, an embodiment in this specification can be combined with another embodiment within a range of not causing a contradiction, unless otherwise specified. Moreover, other embodiments can also be combined with each other within a range of not causing a contradiction.

In this specification and the drawings, when two or more steps or processes are disclosed regarding a method such as a manufacturing method, another step or process that is not disclosed may be executed between the steps or processes that are disclosed, unless otherwise specified. The sequential order of the steps or processes that are disclosed may be any order, unless contradictory.

Each numerical range expressed using a word “to” in this specification and the drawings includes a numerical value preceding the word “to” and a numerical value succeeding the word “to” as its limits, unless otherwise specified. For example, a numerical range defined by the phrase “34 to 38% by mass” is the same as a numerical range defined by the phrase “34% by mass or more and 38% by mass or less”.

Disclosed in an embodiment in this specification is an example in which a mask is used for forming an organic material or an electrode on a substrate when an organic EL display device is manufactured. However, uses of the mask are not specifically limited, and the present embodiment can be applied to masks used for various applications. For example, a mask according to the present embodiment may be used for forming an electrode of an apparatus configured to display or project an image or video for presenting so-called virtual reality (VR) or so-called augmented reality (AR). Alternatively, a mask according to the present embodiment may be used for forming an electrode of a display device other than an organic EL display device, for example, an electrode of a liquid crystal display device or the like. Alternatively, a mask according to the present embodiment may be used for forming an electrode of an organic device other than a display device, for example, an electrode of a pressure sensor or the like.

A first mode of the present disclosure is a method of manufacturing a mask. The mask includes a first portion and a second portion, the first portion including at least one first through-hole group, the second portion including at least one second through-hole group located next to the first through-hole group in a first direction. The method includes: a step of preparing a laminated body that includes an original base material and a resist layer; a first exposure process of exposing the resist layer corresponding to the first portion by using a first exposure mask; a second exposure process of exposing the resist layer corresponding to the second portion by using a second exposure mask; a process of developing the resist layer corresponding to the first portion and the resist layer corresponding to the second portion; and a process of etching the original base material through the resist layer corresponding to the first portion and the resist layer corresponding to the second portion, wherein the first exposure mask includes a first surface first exposure mask, through which the resist layer located on a first surface of the original base material is exposed, and a second surface first exposure mask, through which the resist layer located on a second surface of the original base material is exposed, in the first exposure process, the resist layer located on the first surface is exposed using the first surface first exposure mask, and the resist layer located on the second surface is exposed using the second surface first exposure mask, the second exposure mask includes a first surface second exposure mask, through which the resist layer located on the first surface is exposed, and a second surface second exposure mask, through which the resist layer located on the second surface is exposed, in the second exposure process, the resist layer located on the first surface is exposed using the first surface second exposure mask, and the resist layer located on the second surface is exposed using the second surface second exposure mask, a peripheral edge of the first portion and the first through-hole group are formed through the original base material by etching through the resist layer corresponding to the first portion, and a peripheral edge of the second portion and the second through-hole group are formed through the original base material by etching through the resist layer corresponding to the second portion.

As a second mode of the present disclosure, in the method according to the first mode stated above, the first exposure mask may have a quadrangular shape that includes a first side and a second side. The first side may have a length of 1090 mm or greater. The second side may have a length of 810 mm or greater.

As a third mode of the present disclosure, in the method according to the first mode or the second mode stated above, a thickness of the original base material may be 30 μm or greater.

As a fourth mode of the present disclosure, in the method according to any of the first to third modes stated above, the second exposure process may include a process of adjusting a position of the second exposure mask while taking, as a reference, the resist layer corresponding to the first portion after execution of the first exposure process.

As a fifth mode of the present disclosure, in the method according to any of the first to fourth modes stated above, the second exposure process may include a process of adjusting a position of the second exposure mask while taking, as a reference, a position of the first exposure mask having been used in the first exposure process.

As a sixth mode of the present disclosure, in the method according to any of the first to fifth modes stated above, the first exposure process may include a process of performing a relative position adjustment between the first surface first exposure mask and the second surface first exposure mask, and the second exposure process may include a process of performing a relative position adjustment between the first surface second exposure mask and the second surface second exposure mask.

A seventh mode of the present disclosure is a mask that includes a base material that includes a first side edge and a second side edge extending in a first direction and that includes a first surface and a second surface; and a plurality of through-hole groups going through the base material, wherein in a plan view, the mask includes a first portion and a second portion, the first portion including at least one first through-hole group among the through-hole groups, the second portion including, among the through-hole groups, at least one second through-hole group located next to the first through-hole group in the first direction, a first angle 91 formed by a first array direction of the first through-hole group and a second array direction of the second through-hole group is 0.00042° or greater, the first array direction is an array direction of through holes belonging to the first through-hole group and arranged along the first side edge, and the second array direction is an array direction of through holes belonging to the second through-hole group and arranged along the first side edge.

As an eighth mode of the present disclosure, the mask according to the seventh mode stated above may, in a plan view, include a middle portion that includes the plurality of through-hole groups arranged in the first direction. A dimension of the middle portion in the first direction may be 1000 mm or greater and 2200 mm or less.

As a ninth mode of the present disclosure, in the mask according to the seventh mode or the eighth mode stated above, the first side edge may include a first step portion located at a boundary between the first portion and the second portion and displaced in a second direction orthogonal to the first direction.

As a tenth mode of the present disclosure, in the mask according to the ninth mode stated above, a dimension S1 of the first step portion may be 3.0 μm or less.

As an eleventh mode of the present disclosure, in the mask according to any of the seventh to tenth modes stated above, the first angle θ1 may be 0.00125° or less.

As a twelfth mode of the present disclosure, in the mask according to the ninth mode stated above, a formula of 4820[μm/°]×θ1[°]+S1[μm]≤6.0[μm] may hold between the dimension S1 of the first step portion and the first angle θ1.

As a thirteenth mode of the present disclosure, in the mask according to any of the seventh to twelfth modes stated above, a dimension of the first portion in the first direction may be 900 mm or greater, and a dimension of the second portion in the first direction may be 900 mm or greater.

As a fourteenth mode of the present disclosure, in the mask according to any of the seventh to thirteenth modes stated above, the first portion may include a first end that is an end of the mask in the first direction, and the second portion may include a second end that is an end of the mask in the first direction.

As a fifteenth mode of the present disclosure, in the mask according to the fourteenth mode stated above, in a plan view, each of the first end and the second end may include two or more recesses arranged in a second direction orthogonal to the first direction.

As a sixteenth mode of the present disclosure, in the mask according to the fifteenth mode stated above, the recess may have a dimension of 5 mm or greater in the first direction.

A seventeenth mode of the present disclosure is a method of manufacturing a mask apparatus. The method includes: an alignment step of determining a position of the mask in relation to a frame while applying tension to the mask according to any of the seventh to sixteenth modes stated above; and a fixing step of fixing the mask to the frame, wherein the first portion includes a first inner reference hole that is a through hole of the first through-hole group located next to the second through-hole group in the first direction and a first outer reference hole that is a through hole of, among the through-hole groups, a first through-hole group located farthest from the second through-hole group in the first direction, the second portion includes a second outer reference hole that is a through hole of, among the through-hole groups, a second through-hole group located farthest from the first through-hole group in the first direction, and the alignment step includes an adjustment step and a shift step, the adjustment step being a step of adjusting the tension on a basis of the first outer reference hole and the second outer reference hole, and the shift step being a step of moving the mask in a second direction orthogonal to the first direction after the adjustment step on a basis of the first inner reference hole.

As an eighteenth mode of the present disclosure, in the method according to the seventeenth mode stated above, in the adjustment step, the tension may be adjusted such that, in the second direction, both a deviation distance of the first outer reference hole and a deviation distance of the second outer reference hole become less than or equal to a first adjustment threshold.

As a nineteenth mode of the present disclosure, in the method according to the seventeenth mode or the eighteenth mode stated above, in the shift step, the mask may be moved in the second direction such that, in the second direction, all of the deviation distance of the first outer reference hole, a deviation distance of the first inner reference hole, and the deviation distance of the second outer reference hole become less than or equal to a second adjustment threshold.

As a twentieth mode of the present disclosure, in the method according to the nineteenth mode stated above, in the shift step, the mask may be moved in the second direction such that a difference between the deviation distance of the first outer reference hole and the deviation distance of the first inner reference hole becomes less than or equal to a third adjustment threshold.

As a twenty-first mode of the present disclosure, in the method according to any of the seventeenth to twentieth modes stated above, a dimension of the frame in the second direction may be 1200 mm or greater.

An embodiment of the present disclosure will now be described in detail while referring to the drawings. The embodiment described below is just an example of embodiments of the present disclosure, and the present disclosure shall not be construed to be limited to the embodiments.

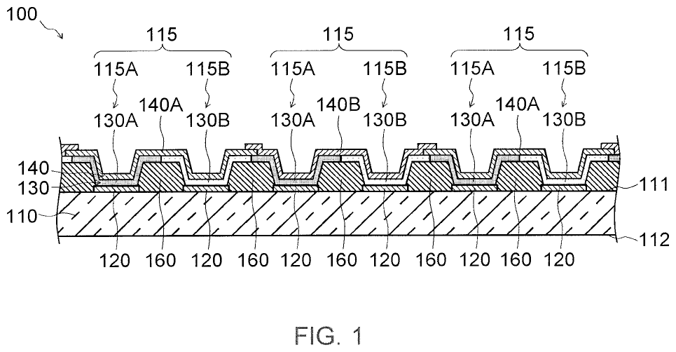

An organic device 100 that includes a component(s) formed using a mask will now be described. FIG. 1 is a cross-sectional view of an example of the organic device 100.

The organic device 100 includes a substrate 110, which includes a first surface 111 and a second surface 112, and a plurality of elements 115, which are located on the first surface 111 of the substrate 110. The element 115 is, for example, a pixel. The elements 115 may be arranged in an in-plane direction of the first surface 111. The substrate 110 may include two or more kinds of elements 115. For example, the substrate 110 may include first elements 115A and second elements 115B. Though not illustrated, the substrate 110 may include third elements. The first element 115A, the second element 1158, and the third element are, for example, a red pixel, a blue pixel, and a green pixel.

The element 115 may include a first electrode 120, an organic layer 130 located on the first electrode 120, and a second electrode 140 located on the organic layer 130. The component formed using a mask may be the organic layer 130 or the second electrode 140. The component formed using a mask will be referred to also as “vapor deposition layer”.

The organic device 100 may include an insulation layer 160 located between two first electrodes 120 adjacent to each other in a plan view. The insulation layer 160 contains, for example, polyimide. The insulation layer 160 may overlap with an end of the first electrode 120 in a plan view.

The organic device 100 may be an active-matrix-type device. For example, the organic device 100 may include switches connected electrically to the plurality of elements 115 respectively. The switch is, for example, a transistor. The switch is capable of controlling ON/OFF of a voltage or a current to the corresponding one of the elements 115.

The substrate 110 may be a plate-like insulating member. Preferably, the substrate 110 should have transparency for allowing light to pass through itself. As the material of the substrate 110, for example, quartz glass, Pyrex® glass, a rigid material that does not have flexibility such as a synthetic silica plate, or a flexible material that has flexibility such as a resin film, an optical resin plate, or thin glass can be used. The base material may be a laminated body that has a barrier layer(s) on one side or both sides of a resin film.

The element 115 is configured to fulfill some sort of function when a voltage is applied between the first electrode 120 and the second electrode 140 or when a current flows between the first electrode 120 and the second electrode 140. For example, in a case where the element 115 is a pixel of an organic EL display device, the element 115 is capable of emitting light that forms video.

The first electrode 120 contains a material that is electrically conductive. For example, the first electrode 120 contains metal, a metallic oxide that is electrically conductive, other inorganic material that is electrically conductive, or the like. The first electrode 120 may contain a metallic oxide that is transparent and electrically conductive such as indium tin oxide (ITO) or indium zinc oxide (IZO).

The organic layer 130 contains an organic material. When the organic layer 130 is electrically energized, the organic layer 130 is capable of fulfilling some sort of function. The meaning of “electrically energized” is that a voltage is applied to the organic layer 130 or a current flows through the organic layer 130. A light emitting layer that emits light when electrically energized can be used as the organic layer 130. The organic layer 130 may contain an organic semiconductor material. The characteristics of the organic layer 130 such as transmittance and refractive index may be adjusted as appropriate.

As illustrated in FIG. 1, the organic layer 130 may include a first organic layer 130A and a second organic layer 130B. The first organic layer 130A is included in the first element 115A. The second organic layer 130B is included in the second element 115B. Though not illustrated, the organic layer 130 may include a third organic layer. The first organic layer 130A, the second organic layer 130B, and the third organic layer are, for example, a red light emitting layer, a blue light emitting layer, and a green light emitting layer.

When a voltage is applied between the first electrode 120 and the second electrode 140, the organic layer 130 located therebetween is driven. In a case where the organic layer 130 is a light emitting layer, light is emitted from the organic layer 130, and the light is taken out from the second electrode 140 side or the first electrode 120 side.

The organic layer 130 may further include a hole injection layer, a hole transport layer, an electron transport layer, an electron injection layer, a charge generation layer, and the like.

The second electrode 140 contains a material that is electrically conductive, for example, metal. The second electrode 140 is formed on the organic layer 130 by means of a vapor deposition method using a mask. Platinum, gold, silver, copper, iron, tin, chromium, aluminum, indium, lithium, sodium, potassium, calcium, magnesium, indium tin oxide (ITO), indium zinc oxide (IZO), carbon, etc. can be used as the material of the second electrode 140. Any of these kinds of material may be used alone, or two or more of them may be used in combination. In a case where two or more kinds of material are used in combination, a layer made of one may be stacked on a layer made of another. Alternatively, an alloy that contains two or more kinds of material may be used. For example, a magnesium alloy such as MgAg or an aluminum alloy such as AlLi, AlCa, or AlMg can be used. MgAg is referred to also as magnesium silver. Magnesium silver can be used as a preferred material of the second electrode 140. Alloys of alkali metals and alkaline earth metals are also usable. For example, lithium fluoride, sodium fluoride, potassium fluoride, or the like may be used.

The second electrode 140 may be a common electrode. For example, the second electrode 140 of one element 115 may be electrically connected to the second electrode 140 of another element 115.

The second electrode 140 may be made of a single layer. For example, the second electrode 140 may be a layer formed through a vapor deposition step using a single mask.

Alternatively, as illustrated in FIG. 1, the second electrode 140 may include a first layer 140A and a second layer 140B. The first layer 140A may be a layer formed through a vapor deposition step using a first mask. The second layer 140B may be a layer formed through a vapor deposition step using a second mask. As described here, the second electrode 140 may be formed using two or more masks. This increases a degree of freedom in patterning of the second electrode 140 in a plan view. For example, the organic device 100 can include an area where the second electrode 140 does not exist in a plan view. The area where the second electrode 140 does not exist can have higher transmittance than an area where the second electrode 140 exists.

As illustrated in FIG. 1, an end portion of the first layer 140A and an end portion of the second layer 140B may partially overlap with each other. This enables electric connection between the first layer 140A and the second layer 140B.

Though not illustrated, the second electrode 140 may include another layer such as a third layer. Another layer such as a third layer may be electrically connected to the first layer 140A and the second layer 140B.

In the description below, the term and reference numeral “second electrode 140” will be used when explaining a structure that is common to the first layer 140A, the second layer 140B, the third layer, and the like that are included in the second electrode 140.

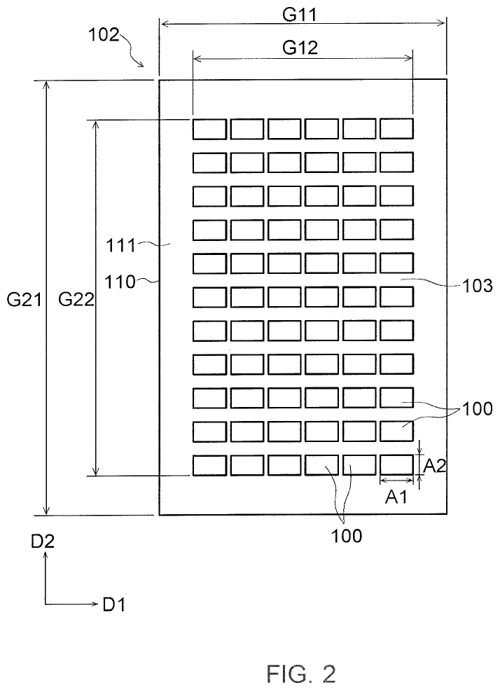

In a method of manufacturing the organic device 100, an organic device group 102 such as one illustrated in FIG. 2 may be produced. The organic device group 102 includes two or more organic devices 100. For example, the organic device group 102 may include organic devices 100 arranged in a first direction D1 and a second direction D2. The second direction D2 is a direction orthogonal to the first direction D1. Two or more organic devices 100 may include a single common substrate 110. For example, the organic device group 102 may include layers of the first electrode 120, the organic layer 130, the second electrode 140, and the like that are located on a single substrate 110 and constitute two or more organic devices 100. Organic devices 100 can be obtained by dividing the organic device group 102.

The first direction D1 may be a direction in which, as will be described later, a mask 50 used for manufacturing the organic device 100 extends.

The dimension A1 of the organic device 100 in the first direction D1 may be, for example, 10 mm or greater, 30 mm or greater, or 100 mm or greater. The dimension A1 may be, for example, 200 mm or less, 500 mm or less, or 1000 mm or less. The range of the dimension A1 may be determined based on a first group consisting of 10 mm, 30 mm, and 100 mm and/or a second group consisting of 200 mm, 500 mm, and 1000 mm. The range of the dimension A1 may be determined based on a combination of any one of the values included in the first group mentioned above and any one of the values included in the second group mentioned above. The range of the dimension A1 may be determined based on a combination of any two of the values included in the first group mentioned above. The range of the dimension A1 may be determined based on a combination of any two of the values included in the second group mentioned above. For example, the dimension A1 may be 10 mm or greater and 1000 mm or less, 10 mm or greater and 500 mm or less, 10 mm or greater and 200 mm or less, 10 mm or greater and 100 mm or less, 10 mm or greater and 30 mm or less, 30 mm or greater and 1000 mm or less, 30 mm or greater and 500 mm or less, 30 mm or greater and 200 mm or less, 30 mm or greater and 100 mm or less, 100 mm or greater and 1000 mm or less, 100 mm or greater and 500 mm or less, 100 mm or greater and 200 mm or less, 200 mm or greater and 1000 mm or less, 200 mm or greater and 500 mm or less, or 500 mm or greater and 1000 mm or less.

The dimension A2 of the organic device 100 in the second direction D2 may be, for example, 10 mm or greater, 20 mm or greater, or 50 mm or greater. The dimension A2 may be, for example, 100 mm or less, 200 mm or less, or 500 mm or less. The range of the dimension A2 may be determined based on a first group consisting of 10 mm, 20 mm, and 50 mm and/or a second group consisting of 100 mm, 200 mm, and 500 mm. The range of the dimension A2 may be determined based on a combination of any one of the values included in the first group mentioned above and any one of the values included in the second group mentioned above. The range of the dimension A2 may be determined based on a combination of any two of the values included in the first group mentioned above. The range of the dimension A2 may be determined based on a combination of any two of the values included in the second group mentioned above. For example, the dimension A2 may be 10 mm or greater and 500 mm or less, 10 mm or greater and 200 mm or less, 10 mm or greater and 100 mm or less, 10 mm or greater and 50 mm or less, 10 mm or greater and 20 mm or less, 20 mm or greater and 500 mm or less, 20 mm or greater and 200 mm or less, 20 mm or greater and 100 mm or less, 20 mm or greater and 50 mm or less, 50 mm or greater and 500 mm or less, 50 mm or greater and 200 mm or less, 50 mm or greater and 100 mm or less, 100 mm or greater and 500 mm or less, 100 mm or greater and 200 mm or less, or 200 mm or greater and 500 mm or less.

The organic device group 102 includes a device area 103 where the plurality of organic devices 100 is located. The device area 103 has a dimension G12 in the first direction D1 and a dimension G22 in the second direction D2.

Increasing the size of the substrate 110 makes it possible to increase the dimensions G12 and G22 of the device area 103. This increases the number of organic devices 100 formed on a single substrate 110, thereby reducing the manufacturing cost of the organic device 100.

The dimension G11 of the substrate 110 in the first direction D1 may be, for example, 1000 mm or greater, 1200 mm or greater, 1300 mm or greater, or 2100 mm or greater. The dimension G11 may be, for example, 1200 mm or less, 1300 mm or less, 1900 mm or less, 2100 mm or less, or 2300 mm or less. The range of the dimension G11 may be determined based on a first group consisting of 1000 mm, 1200 mm, 1300 mm, and 2100 mm and/or a second group consisting of 1200 mm, 1300 mm, 1900 mm, 2100 mm, and 2300 mm. The range of the dimension G11 may be determined based on a combination of any one of the values included in the first group mentioned above and any one of the values included in the second group mentioned above. The range of the dimension G11 may be determined based on a combination of any two of the values included in the first group mentioned above. The range of the dimension G11 may be determined based on a combination of any two of the values included in the second group mentioned above. For example, the dimension G11 may be 1000 mm or greater and 2300 mm or less, 1000 mm or greater and 2100 mm or less, 1000 mm or greater and 1900 mm or less, 1000 mm or greater and 1300 mm or less, 1000 mm or greater and 1200 mm or less, 1200 mm or greater and 2300 mm or less, 1200 mm or greater and 2100 mm or less, 1200 mm or greater and 1900 mm or less, 1200 mm or greater and 1300 mm or less, 1300 mm or greater and 2300 mm or less, 1300 mm or greater and 2100 mm or less, 1300 mm or greater and 1900 mm or less, 1900 mm or greater and 2300 mm or less, 1900 mm or greater and 2100 mm or less, or 2100 mm or greater and 2300 mm or less.

The dimension G21 of the substrate 110 in the second direction D2 may be, for example, 1200 mm or greater, 1300 mm or greater, 1500 mm or greater, 2000 mm or greater, or 2400 mm or greater. The dimension G21 may be, for example, 1300 mm or less, 2300 mm or less, 2400 mm or less, or 2600 mm or less. The range of the dimension G21 may be determined based on a first group consisting of 1200 mm, 1300 mm, 1500 mm, 2000 mm, and 2400 mm and/or a second group consisting of 1300 mm, 2300 mm, 2400 mm, and 2600 mm. The range of the dimension G21 may be determined based on a combination of any one of the values included in the first group mentioned above and any one of the values included in the second group mentioned above. The range of the dimension G21 may be determined based on a combination of any two of the values included in the first group mentioned above. The range of the dimension G21 may be determined based on a combination of any two of the values included in the second group mentioned above. For example, the dimension G21 may be 1200 mm or greater and 2600 mm or less, 1200 mm or greater and 2400 mm or less, 1200 mm or greater and 2300 mm or less, 1200 mm or greater and 1500 mm or less, 1200 mm or greater and 1300 mm or less, 1300 mm or greater and 2600 mm or less, 1300 mm or greater and 2400 mm or less, 1300 mm or greater and 2300 mm or less, 1300 mm or greater and 1500 mm or less, 1500 mm or greater and 2600 mm or less, 1500 mm or greater and 2400 mm or less, 1500 mm or greater and 2300 mm or less, 2000 mm or greater and 2300 mm or less, 2300 mm or greater and 2600 mm or less, 2300 mm or greater and 2400 mm or less, or 2400 mm or greater and 2600 mm or less.

A particular numerical range of the dimension G11 may be combined with a particular numerical range of the dimension G21. For example, the dimension G11 may be 1000 mm or greater and 1200 mm or less, and the dimension G21 may be 1200 mm or greater and 1300 mm or less. For example, the dimension G11 may be 1200 mm or greater and 1300 mm or less, and the dimension G21 may be 2000 mm or greater and 2300 mm or less. For example, the dimension G11 may be 2100 mm or greater and 2300 mm or less, and the dimension G21 may be 2400 mm or greater and 2600 mm or less.

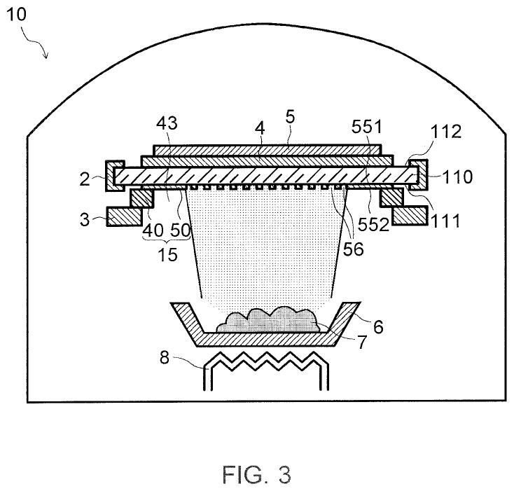

Next, a method of forming a component(s) such as the organic layer 130, the second electrodes 140, etc. by means of a vapor deposition method will now be described. FIG. 3 is a diagram that illustrates a vapor deposition apparatus 10. The vapor deposition apparatus 10 performs vapor deposition processing of depositing a vapor deposition material onto the substrate 110.

As illustrated in FIG. 3, the vapor deposition apparatus 10 may include an evaporation source 6, a heater 8, and a mask apparatus 15 inside. The vapor deposition apparatus 10 may further include an exhausting means configured to make the inside of the vapor deposition apparatus 10 vacuum. The evaporation source 6 is, for example, a crucible and contains a vapor deposition material 7 such as an organic material or a metal material. The heater 8 heats the evaporation source 6 so as to evaporate the vapor deposition material 7 in vacuum atmosphere. The mask apparatus 15 is disposed facing the crucible 6.

As illustrated in FIG. 3, the mask apparatus 15 includes at least one mask 50. The mask apparatus 15 may include a mask support 40 that supports the mask 50. The mask support 40 may include a frame 41 with an opening 43. The mask 50 may be fixed to the frame 41 across the opening 43 in a plan view. The frame 41 may support the mask 50 in a state of applying tension thereto in its plane direction so as to suppress a sag in the mask 50.

As illustrated in FIG. 3, the mask apparatus 15 is disposed inside the vapor deposition apparatus 10 such that the mask 50 faces the first surface 111 of the substrate 110. The mask 50 has a plurality of through holes 56 through which the vapor deposition material 7 coming from the evaporation source 6 passes. In the description below, the surface, of the mask 50, facing the substrate 110 will be referred to as “first surface 551”. The surface, of the mask 50, located at the opposite side in relation to the first surface 551 will be referred to as “second surface 552”.

As illustrated in FIG. 3, the vapor deposition apparatus 10 may include a substrate holder 2 that holds the substrate 110. The substrate holder 2 may be movable in the thickness direction of the substrate 110. The substrate holder 2 may be movable in the plane direction of the substrate 110. The substrate holder 2 may be configured to control the tilt of the substrate 110. For example, the substrate holder 2 may include a plurality of chucks attached to the peripheral edges of the substrate 110. Each chuck may be movable independently in the thickness direction of the substrate 110 and the plane direction thereof.

The position of the mask 50 in relation to the substrate 110 can be adjusted by moving at least one of the substrate holder 2 or a mask holder 3.

As illustrated in FIG. 3, the vapor deposition apparatus 10 may include a cooling board 4 disposed at the second surface 112 side of the substrate 110. The cooling board 4 may include a flow passage, and a coolant may be circulated inside the cooling board 4 through the flow passage. The cooling board 4 is capable of suppressing a rise in temperature of the substrate 110 when the vapor deposition step is executed.

As illustrated in FIG. 3, the vapor deposition apparatus 10 may include a magnet 5 disposed at the second surface 112 side of the substrate 110. The magnet 5 may be disposed on, of the cooling board 4, the surface that is farther from the substrate 110. The magnet 5 is capable of magnetically attract the mask 50 toward the substrate 110. The magnetic attraction makes it possible to reduce a gap between the mask 50 and the substrate 110 or eliminate the gap. This makes it possible to suppress the occurrence of a shadow in the vapor deposition step. A shadow is a phenomenon that the vapor deposition material 7 enters a gap between the mask 50 and the substrate 110, resulting in making the shape of a vapor deposition layer non-uniform. The shape of a vapor deposition layer includes the thickness of the vapor deposition layer, the dimensions of the vapor deposition layer in a plan view, and the like. The mask 50 may be attracted toward the substrate 110 by using an electrostatic chuck that utilizes an electrostatic force.

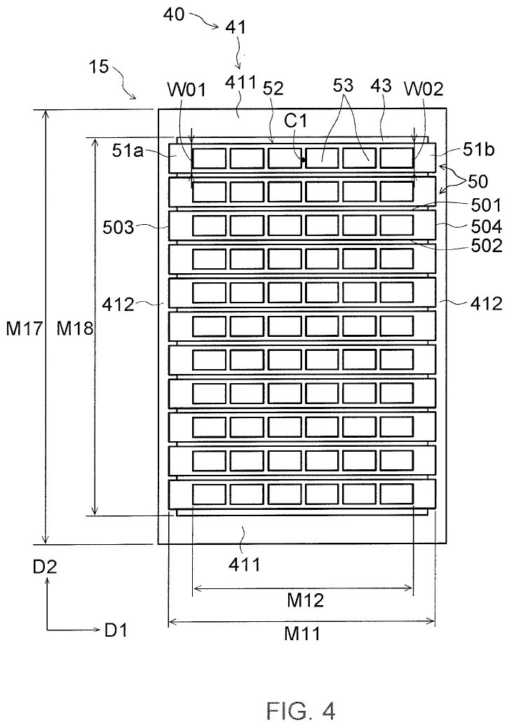

FIG. 4 is a plan view of the mask apparatus 15 viewed from the first surface 551 side. The mask apparatus 15 may include the mask support 40, which includes the frame 41, and the mask 50, which is fixed to the frame 41. The mask apparatus 15 may include two or more masks 50 arranged in the second direction D2. The frame 41 supports the mask 50 in a state in which tension is applied to the mask 50 so as to suppress a sag in the mask 50.

The frame 41 may include a pair of first sides 411 extending in the first direction D1, a pair of second sides 412 extending in the second direction D2, and the opening 43. The second side 412 may be longer than the first side 411. The opening 43 is located between the pair of first sides 411 and between the pair of second sides 412.

The mask 50 may include a first side edge 501 and a second side edge 502, which extend in the first direction D1, and a first end 503 and a second end 504. The first end 503 and the second end 504 are the ends of the mask 50 in the first direction D1.

In a plan view, the mask 50 includes a first end portion 51a, a second end portion 51b, and a middle portion 52. The first end portion 51a and the second end portion 51b are the opposite of each other in the first direction D1. The middle portion 52 is located between the first end portion 51a and the second end portion 51b. The middle portion 52 includes a plurality of through-hole groups 53 arranged in the first direction D1.

The first end portion 51a has a width W01. The width W01 is the dimension of the first end portion 51a in the second direction D2. The width W01 is measured at the boundary between the first end portion 51a and the middle portion 52. The second end portion 51b has a width W02. The width W02 is the dimension of the second end portion 51b in the second direction D2. The width W02 is measured at the boundary between the second end portion 51b and the middle portion 52.

The width W01 of the first end portion 51a may be equal to the width W02 of the second end portion 51b, or may be greater than the width W02 or less than the width W02.

The term “plan view” means that the object is viewed in the thickness direction of the mask 50.

The mask 50 is fixed to the second sides 412. Specifically, the first end portion 51a is fixed to one of the second sides 412, and the second end portion 51b is fixed to the other of the second sides 412. The first end portion 51a and the second end portion 51b may be fixed to the second sides 412 by welding. The middle portion 52 overlaps with the opening 43 of the frame 41 in a plan view.

The frame 41 has a dimension M17 in the second direction D2. The above-described numerical range of the dimension G21 of the substrate 110 can be adopted as the numerical range of the dimension M17. The opening 43 of the frame 41 has a dimension M18 in the second direction D2. Increasing the dimension M17 of the frame 41 makes it possible to increase the dimension M18 of the opening 43, thereby increasing the dimension G22 of the device area 103 of the organic device group 102. This makes it possible to reduce the manufacturing cost of the organic device 100.

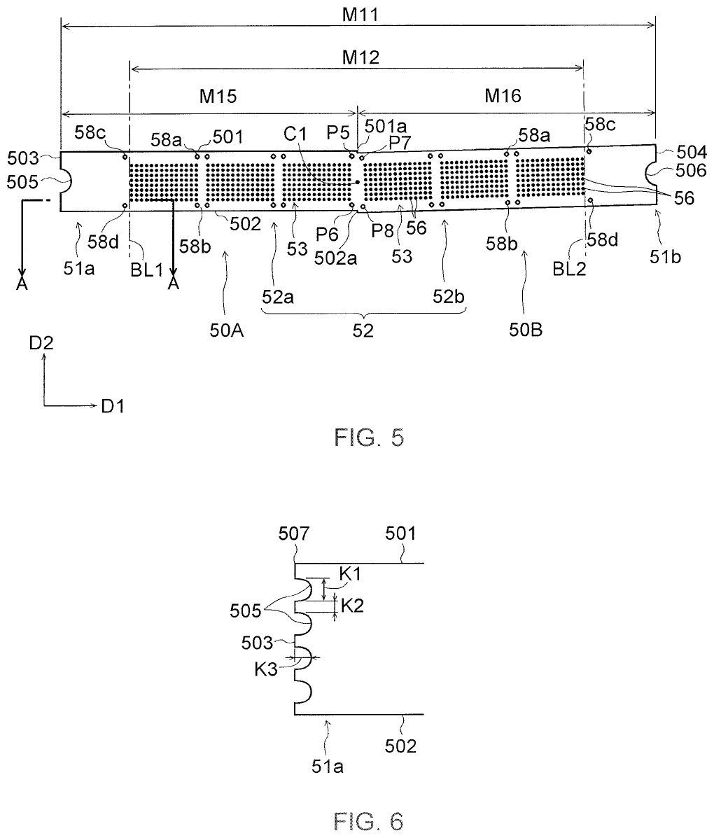

FIG. 5 is a plan view of an example of the mask 50. The through-hole group 53 of the middle portion 52 includes a plurality of through holes 56 arranged regularly in a plan view. The through holes 56 may be arranged periodically in two directions. For example, the through holes 56 may be arranged periodically in the first direction D1 and the second direction D2.

One through-hole group 53 corresponds to one organic device 100. For example, plural pieces of the first organic layer 130A included in one organic device 100 are made of the vapor deposition material having passed through the plurality of through holes 56 of one through-hole group 53. The mask 50 includes at least one through-hole group 53. The mask 50 may include two or more through-hole groups 53 arranged in the first direction D1.

The mask 50 has a dimension M11 in the first direction D1. The middle portion 52 has a dimension M12 in the first direction D1. The boundary between the middle portion 52 and the first end portion 51a is determined based on, among the through-hole groups 53, the one located closest to the first end 503. As illustrated in FIG. 5, a borderline BL1 that indicates the boundary extends in the second direction D2 alongside a plurality of through holes 56 located closest to the first end 503. Similarly, the boundary between the middle portion 52 and the second end portion 51b is determined based on, among the through-hole groups 53, the one located closest to the second end 504. As illustrated in FIG. 5, a borderline BL2 that indicates the boundary extends in the second direction D2 alongside a plurality of through holes 56 located closest to the second end 504.

FIG. 6 is a plan view of an example of the first end portion 51a of the mask 50. As illustrated in FIG. 6, the first end 503 may include two or more recesses 505 arranged in the second direction D2. The recess 505 is recessed inward in the first direction D1. “Inward” means a directional side of coming closer to the center of the mask 50. “Inward in the first direction D1” means a directional side of coming closer to the center of the mask 50 in the first direction D1. The recess 505 may be recessed inward in the first direction D1 with respect to a corner 507. The corner 507 is a portion where the first side edge 501 and the first end 503 meet.

As will be described later, in an alignment step of determining the position of the mask 50 in relation to the frame 41, tension is applied to the mask 50 via clamps. The clamp is attached to, of the first end 503, a portion where no recess 505 is formed. Since the first end 503 includes two or more recesses 505, it is possible to attach three or more clamps to the first end 503. This makes it possible to suppress tension variations according to position in the second direction D2.

The recess 505 has a dimension K1 in the second direction D2. The dimension K1 may be, for example, 5 mm or greater, 15 mm or greater, or 20 mm or greater. The dimension K1 may be, for example, 30 mm or less, 40 mm or less, or 50 mm or less. The range of the dimension K1 may be determined based on a first group consisting of 5 mm, 15 mm, and 20 mm and/or a second group consisting of 30 mm, 40 mm, and 50 mm. The range of the dimension K1 may be determined based on a combination of any one of the values included in the first group mentioned above and any one of the values included in the second group mentioned above. The range of the dimension K1 may be determined based on a combination of any two of the values included in the first group mentioned above. The range of the dimension K1 may be determined based on a combination of any two of the values included in the second group mentioned above. The dimension K1 may be, for example, 5 mm or greater and 50 mm or less, 5 mm or greater and 40 mm or less, 5 mm or greater and 30 mm or less, 5 mm or greater and 20 mm or less, 5 mm or greater and 15 mm or less, 15 mm or greater and 50 mm or less, 15 mm or greater and 40 mm or less, 15 mm or greater and 30 mm or less, 15 mm or greater and 20 mm or less, 20 mm or greater and 50 mm or less, 20 mm or greater and 40 mm or less, 20 mm or greater and 30 mm or less, 30 mm or greater and 50 mm or less, 30 mm or greater and 40 mm or less, or 40 mm or greater and 50 mm or less.

In FIG. 6, the reference sign K2 denotes an interval between two recesses 505 located next to each other in the second direction D2. The interval K2 may be, for example, 10 mm or greater, 20 mm or greater, or 30 mm or greater. The interval K2 may be, for example, 40 mm or less, 50 mm or less, or 60 mm or less. The range of the interval K2 may be determined based on a first group consisting of 10 mm, 20 mm, and 30 mm and/or a second group consisting of 40 mm, 50 mm, and 60 mm. The range of the interval K2 may be determined based on a combination of any one of the values included in the first group mentioned above and any one of the values included in the second group mentioned above. The range of the interval K2 may be determined based on a combination of any two of the values included in the first group mentioned above. The range of the interval K2 may be determined based on a combination of any two of the values included in the second group mentioned above. The interval K2 may be, for example, 10 mm or greater and 60 mm or less, 10 mm or greater and 50 mm or less, 10 mm or greater and 40 mm or less, 10 mm or greater and 30 mm or less, 10 mm or greater and 20 mm or less, 20 mm or greater and 60 mm or less, 20 mm or greater and 50 mm or less, 20 mm or greater and 40 mm or less, 20 mm or greater and 30 mm or less, 30 mm or greater and 60 mm or less, 30 mm or greater and 50 mm or less, 30 mm or greater and 40 mm or less, 40 mm or greater and 60 mm or less, 40 mm or greater and 50 mm or less, or 50 mm or greater and 60 mm or less.

The recess 505 has a dimension K3 in the first direction D1. The dimension K3 may be, for example, 15 mm or greater, 20 mm or greater, or 25 mm or greater. The dimension K3 may be, for example, 30 mm or less, 40 mm or less, or 50 mm or less. The range of the dimension K3 may be determined based on a first group consisting of 15 mm, 20 mm, and 25 mm and/or a second group consisting of 30 mm, 40 mm, and 50 mm. The range of the dimension K3 may be determined based on a combination of any one of the values included in the first group mentioned above and any one of the values included in the second group mentioned above. The range of the dimension K3 may be determined based on a combination of any two of the values included in the first group mentioned above. The range of the dimension K3 may be determined based on a combination of any two of the values included in the second group mentioned above. The dimension K3 may be, for example, 15 mm or greater and 50 mm or less, 15 mm or greater and 40 mm or less, 15 mm or greater and 30 mm or less, 15 mm or greater and 25 mm or less, 15 mm or greater and 20 mm or less, 20 mm or greater and 50 mm or less, 20 mm or greater and 40 mm or less, 20 mm or greater and 30 mm or less, 20 mm or greater and 25 mm or less, 25 mm or greater and 50 mm or less, 25 mm or greater and 40 mm or less, 25 mm or greater and 30 mm or less, 30 mm or greater and 50 mm or less, 30 mm or greater and 40 mm or less, or 40 mm or greater and 50 mm or less.

In order to make the substrate 110 of the organic device group 102 illustrated in FIG. 2 larger, an increase in the dimension M11 of the mask 50 is needed. As the size of the mask 50 increases, so does the size of manufacturing facilities for mask production. For example, in order to manufacture a mask corresponding to an eighth-generation substrate, an exposure mask corresponding to the eighth-generation substrate is needed. However, making the exposure mask larger requires a heavy investment.

The present embodiment proposes manufacturing one mask 50 by executing an exposure step twice or more. With this method, it is possible to manufacture a mask 50 that has greater dimensions than the dimensions of an exposure mask. For this reason, it is possible to manufacture a large-sized mask 50 by using an existing exposure mask.

The present embodiment proposes forming a first portion 50A by using a first exposure mask and forming a second portion 50B by using a second exposure mask. The second portion 50B adjoins the first portion 50A in the first direction D1. That is, in the present embodiment, the exposure step is executed twice at different positions in the first direction D1. This makes it possible to increase the dimension of the mask 50 in the first direction D1.

The first portion 50A includes at least a first middle portion 52a. The second portion 50B includes at least a second middle portion 52b. As illustrated in FIG. 5, the first middle portion 52a is a part of the middle portion 52, and this part adjoins the first end portion 51a in the first direction D1. The second middle portion 52b is a part of the middle portion 52, and this part adjoins the second end portion 51b in the first direction D1. The middle portion 52 is made up of the first middle portion 52a and the second middle portion 52b. The first middle portion 52a and the second middle portion 52b adjoin each other in the first direction D1. As described above, in the present embodiment, the middle portion 52 is formed by executing the exposure step twice or more. This makes it possible to increase the dimension of the middle portion 52 in the first direction D1 effectively.

As illustrated in FIG. 5, the first portion 50A may include the first middle portion 52a and the first end portion 51a. That is, the first middle portion 52a and the first end portion 51a may be formed using the first exposure mask. In this case, the first portion 50A includes the first end 503. As illustrated in FIG. 5, the second portion 50B may include the second middle portion 52b and the second end portion 51b. That is, the second middle portion 52b and the second end portion 51b may be formed using the second exposure mask. In this case, the second portion 50B includes the second end 504.

For example, when the entire mask 50 is formed using a G6-half exposure mask, the dimension M11 of the mask 50 is approximately 1200 mm, and the dimension M12 of the middle portion 52 is approximately 900 mm. Forming the first portion 50A and the second portion 50B by using two G6-half exposure masks makes it possible to increase the dimension M11 of the mask 50 to approximately 2400 mm and the dimension M12 of the middle portion 52 to approximately 2100 mm.

The dimension M12 of the middle portion 52 in the first direction D1 is the same as the dimension G12 of the device area 103 illustrated in FIG. 2. This makes it possible to form, for example, the first organic layer 130A of the two or more organic devices 100 arranged in the first direction D1 in FIG. 2 by means of a vapor deposition method using a single mask 50. In other words, it is possible to increase the dimension G12 of the device area 103 by increasing the dimension M12 of the middle portion 52 in the first direction D1. This makes it possible to reduce the manufacturing cost of the organic device 100.

The dimension M12 of the middle portion 52 may be, for example, 1000 mm or greater, 1200 mm or greater, 1400 mm or greater, or 1700 mm or greater. The dimension M12 may be, for example, 2000 mm or less, 2300 mm or less, 2600 mm or less, or 3000 mm or less. The range of the dimension M12 may be determined based on a first group consisting of 1000 mm, 1200 mm, 1400 mm, and 1700 mm and/or a second group consisting of 2000 mm, 2300 mm, 2600 mm, and 3000 mm. The range of the dimension M12 may be determined based on a combination of any one of the values included in the first group mentioned above and any one of the values included in the second group mentioned above. The range of the dimension M12 may be determined based on a combination of any two of the values included in the first group mentioned above. The range of the dimension M12 may be determined based on a combination of any two of the values included in the second group mentioned above. The dimension M12 may be, for example, 1000 mm or greater and 3000 mm or less, 1000 mm or greater and 2600 mm or less, 1000 mm or greater and 2300 mm or less, 1000 mm or greater and 2000 mm or less, 1000 mm or greater and 1700 mm or less, 1000 mm or greater and 1400 mm or less, 1000 mm or greater and 1200 mm or less, 1200 mm or greater and 3000 mm or less, 1200 mm or greater and 2600 mm or less, 1200 mm or greater and 2300 mm or less, 1200 mm or greater and 2000 mm or less, 1200 mm or greater and 1700 mm or less, 1200 mm or greater and 1400 mm or less, 1400 mm or greater and 3000 mm or less, 1400 mm or greater and 2600 mm or less, 1400 mm or greater and 2300 mm or less, 1400 mm or greater and 2000 mm or less, 1400 mm or greater and 1700 mm or less, 1700 mm or greater and 3000 mm or less, 1700 mm or greater and 2600 mm or less, 1700 mm or greater and 2300 mm or less, 1700 mm or greater and 2000 mm or less, 2000 mm or greater and 3000 mm or less, 2000 mm or greater and 2600 mm or less, 2000 mm or greater and 2300 mm or less, 2300 mm or greater and 3000 mm or less, 2300 mm or greater and 2600 mm or less, or 2600 mm or greater and 3000 mm or less.

The first portion 50A has a dimension M15 in the first direction D1. The dimension M15 may be 900 mm or greater, 1090 mm or greater, 1200 mm or greater, or 2000 mm or greater. The dimension M15 may be, for example, 1100 mm or less, 1200 mm or less, 1800 mm or less, 2000 mm or less, or 2200 mm or less. The range of the dimension M15 may be determined based on a first group consisting of 900 mm, 1090 mm, 1200 mm, and 2000 mm and/or a second group consisting of 1100 mm, 1200 mm, 1800 mm, 2000 mm, and 2200 mm. The range of the dimension M15 may be determined based on a combination of any one of the values included in the first group mentioned above and any one of the values included in the second group mentioned above. The range of the dimension M15 may be determined based on a combination of any two of the values included in the first group mentioned above. The range of the dimension M15 may be determined based on a combination of any two of the values included in the second group mentioned above. For example, the dimension M15 may be 900 mm or greater and 2200 mm or less, 900 mm or greater and 2000 mm or less, 900 mm or greater and 1800 mm or less, 900 mm or greater and 1200 mm or less, 900 mm or greater and 1100 mm or less, 1090 mm or greater and 2200 mm or less, 1090 mm or greater and 2000 mm or less, 1090 mm or greater and 1800 mm or less, 1090 mm or greater and 1200 mm or less, 1200 mm or greater and 2200 mm or less, 1200 mm or greater and 2000 mm or less, 1200 mm or greater and 1800 mm or less, 1800 mm or greater and 2200 mm or less, 1800 mm or greater and 2000 mm or less, or 2000 mm or greater and 2200 mm or less.

The second portion 50B has a dimension M16 in the first direction D1. The above-described numerical range of the dimension M15 can be adopted as the range of the dimension M16.

The ratio of the dimension M16 of the second portion 50B to the dimension M15 of the first portion 50A, M16/M15, may be, for example, 0.5 or higher, 0.7 or higher, or 0.9 or higher. The ratio M16/M15 may be, for example, 1.1 or lower, 1.3 or lower, or 1.5 or lower. The range of M16/M15 may be determined based on a first group consisting of 0.5, 0.7, and 0.9 and/or a second group consisting of 1.1, 1.3, and 1.5. The range of M16/M15 may be determined based on a combination of any one of the values included in the first group mentioned above and any one of the values included in the second group mentioned above. The range of M16/M15 may be determined based on a combination of any two of the values included in the first group mentioned above. The range of M16/M15 may be determined based on a combination of any two of the values included in the second group mentioned above. For example, M16/M15 may be 0.5 or higher and 1.5 or lower, 0.5 or higher and 1.3 or lower, 0.5 or higher and 1.1 or lower, 0.5 or higher and 0.9 or lower, 0.5 or higher and 0.7 or lower, 0.7 or higher and 1.5 or lower, 0.7 or higher and 1.3 or lower, 0.7 or higher and 1.1 or lower, 0.7 or higher and 0.9 or lower, 0.9 or higher and 1.5 or lower, 0.9 or higher and 1.3 or lower, 0.9 or higher and 1.1 or lower, 1.1 or higher and 1.5 or lower, 1.1 or higher and 1.3 or lower, or 1.3 or higher and 1.5 or lower.

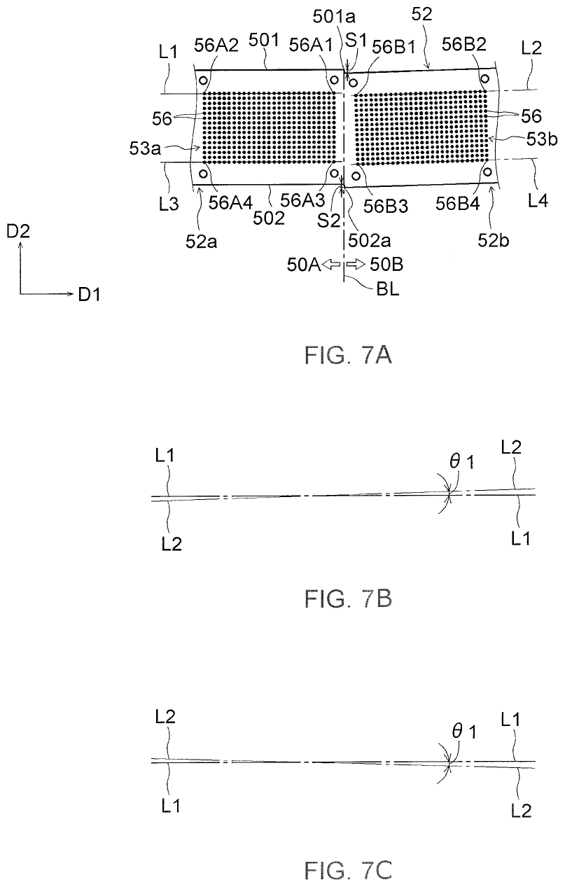

With reference to FIGS. 5 and 7A, structural features observable in the mask 50 manufactured using the method according to the present embodiment will now be described in detail. FIG. 7A is a plan view of an example of the first middle portion 52a and the second middle portion 52b.

The first portion 50A includes at least one through-hole group 53. The second portion 50B also includes at least one through-hole group 53. In the description below, the through-hole group 53 of the first portion 50A will be referred to also as “first through-hole group” and denoted as 53a. In the description below, the through-hole group 53 of the second portion 50B will be referred to also as “second through-hole group” and denoted as 53b.

In FIG. 7A, a borderline BL between the first portion 50A and the second portion 50B is indicated by a dot-and-dash line extending in the second direction D2. The second portion 50B includes the second through-hole group 53b located next to the first through-hole group 53a of the first portion 50A in the first direction D1. The boundary between the first portion 50A and the second portion 50B is located between the first through-hole group 53a and the second through-hole group 53b.

As illustrated in FIG. 7A, the first side edge 501 may include a first step portion 501a located at the boundary between the first portion 50A and the second portion 50B. In other words, the first portion 50A and the second portion 50B may be distinguished from each other based on the first step portion 501a demarcating the boundary therebetween. The position of the first step portion 501a in the first direction D1 should preferably lie between two through-hole groups 53 located next to each other in the first direction D1. In other words, when the mask 50 is viewed in the second direction D2, it is preferable if the first step portion 501a does not overlap with any through-hole group 53.

Though not illustrated, the position of the first step portion 501a in the first direction D1 may lie within the range of one through-hole group 53. That is, when the mask 50 is viewed in the second direction D2, the first step portion 501a may overlap with the through-hole group 53. In this case, the position of the first step portion 501a in the first direction D1 lies between two through holes 56 included in one through-hole group 53 and located next to each other. That is, when the mask 50 is viewed in the second direction D2, the first step portion 501a does not overlap with any through hole 56.

The first step portion 501a is displaced in the second direction D2. In the example illustrated in FIG. 7A, the first step portion 501a is displaced outward in the second direction D2 as viewed toward the first end 503 in the first direction D1. That is, the first side edge 501 of the first portion 50A is located outward of the first side edge 501 of the second portion 50B in the second direction D2. “Outward in the second direction D2” means a directional side of going away from the center C1 of the mask 50 in the second direction D2. Though not illustrated, the first step portion 501a may be displaced inward in the second direction D2 as viewed toward the first end 503 in the first direction D1. That is, the first side edge 501 of the first portion 50A may be located inward of the first side edge 501 of the second portion 50B in the second direction D2. “Inward in the second direction D2” means a directional side of coming closer to the center C1 of the mask 50 in the second direction D2. The center C1 of the mask 50 is located at a midpoint between the borderline BL1 and the borderline BL2.

The first step portion 501a is produced due to the fact that a forming step of the first portion 50A and a forming step of the second portion 50B are different steps. For example, the first step portion 501a is produced due to the fact that the first exposure mask used for forming the first portion 50A and the second exposure mask used for forming the second portion 50B are different from each other. When the relative position of the second exposure mask in relation to the first exposure mask deviates from its ideal position in the second direction D2, the first step portion 501a is produced in accordance with an amount of this deviation. The first step portion 501a has a dimension S1 in the second direction D2. The dimension S1 may be, for example, 0.1 μm or greater, 0.2 μm or greater, 0.5 μm or greater, or 1.0 μm or greater. The dimension S1 may be, for example, 1.5 μm or less, 2.0 μm or less, 2.5 μm or less, or 3.0 μm or less. The range of the dimension S1 may be determined based on a first group consisting of 0.1 μm, 0.2 μm, 0.5 μm, and 1.0 μm and/or a second group consisting of 1.5 μm, 2.0 μm, 2.5 μm, and 3.0 μm. The range of the dimension S1 may be determined based on a combination of any one of the values included in the first group mentioned above and any one of the values included in the second group mentioned above. The range of the dimension S1 may be determined based on a combination of any two of the values included in the first group mentioned above. The range of the dimension S1 may be determined based on a combination of any two of the values included in the second group mentioned above. The dimension S1 may be, for example, 0.1 μm or greater and 3.0 μm or less, 0.1 μm or greater and 2.5 μm or less, 0.1 μm or greater and 2.0 μm or less, 0.1 μm or greater and 1.5 μm or less, 0.1 μm or greater and 1.0 μm or less, 0.1 μm or greater and 0.5 μm or less, 0.1 μm or greater and 0.2 μm or less, 0.2 μm or greater and 3.0 μm or less, 0.2 μm or greater and 2.5 μm or less, 0.2 μm or greater and 2.0 μm or less, 0.2 μm or greater and 1.5 μm or less, 0.2 μm or greater and 1.0 μm or less, 0.2 μm or greater and 0.5 μm or less, 0.5 μm or greater and 3.0 μm or less, 0.5 μm or greater and 2.5 μm or less, 0.5 μm or greater and 2.0 μm or less, 0.5 μm or greater and 1.5 μm or less, 0.5 μm or greater and 1.0 μm or less, 1.0 μm or greater and 3.0 μm or less, 1.0 μm or greater and 2.5 μm or less, 1.0 μm or greater and 2.0 μm or less, 1.0 μm or greater and 1.5 μm or less, 1.5 μm or greater and 3.0 μm or less, 1.5 μm or greater and 2.5 μm or less, 1.5 μm or greater and 2.0 μm or less, 2.0 μm or greater and 3.0 μm or less, 2.0 μm or greater and 2.5 μm or less, or 2.5 μm or greater and 3.0 μm or less.

As illustrated in FIG. 7A, the second side edge 502 may include a second step portion 502a. The second step portion 502a may be located at the boundary between the first portion 50A and the second portion 50B. The position of the second step portion 502a in the first direction D1 should preferably lie between two through-hole groups 53 located next to each other in the first direction D1. In other words, when the mask 50 is viewed in the second direction D2, it is preferable if the second step portion 502a does not overlap with any through-hole group 53.

Though not illustrated, the position of the second step portion 502a in the first direction D1 may lie within the range of one through-hole group 53. That is, when the mask 50 is viewed in the second direction D2, the second step portion 502a may overlap with the through-hole group 53. In this case, the position of the second step portion 502a in the first direction D1 lies between two through holes 56 included in one through-hole group 53 and located next to each other. That is, when the mask 50 is viewed in the second direction D2, the second step portion 502a does not overlap with any through hole 56.

Though not illustrated, the second side edge 502 does not necessarily have to include the second step portion 502a.

The second step portion 502a has a dimension S2 in the second direction D2. The above-described numerical range of the dimension S1 of the first step portion 501a can be adopted as the numerical range of the dimension S2.

As illustrated in FIG. 7A, the length direction of the second portion 50B is slightly different from that of the first portion 50A. For example, a first array direction of the first through-hole group 53a and a second array direction of the second through-hole group 53b form a first angle. In other words, the first array direction and the second array direction are not parallel to each other.

The first array direction is an array direction of through holes 56 belonging to the first through-hole group 53a located next to the second through-hole group 53b and arranged along the first side edge 501. The first array direction is indicated by a straight line L1 illustrated in FIG. 7A. The straight line L1 goes through a plurality of through holes 56 arranged along the first side edge 501 among those of the first through-hole group 53a. For example, the straight line L1 goes through a through hole 56A1 and a through hole 56A2. The through hole 56A1 is the through hole 56 located closest to the first side edge 501 and closest to the second portion 50B among the through holes 56 of the first through-hole group 53a located next to the second through-hole group 53b. The through hole 56A2 is the through hole 56 located closest to the first side edge 501 and farthest from the second portion 50B among the through holes 56 of the first through-hole group 53a located next to the second through-hole group 53b.

The second array direction is an array direction of through holes 56 belonging to the second through-hole group 53b located next to the first through-hole group 53a and arranged along the first side edge 501. The second array direction is indicated by a straight line L2 illustrated in FIG. 7A. The straight line L2 goes through a plurality of through holes 56 arranged along the first side edge 501 among those of the second through-hole group 53b. For example, the straight line L2 goes through a through hole 5661 and a through hole 5662. The through hole 5661 is the through hole 56 located closest to the first side edge 501 and closest to the first portion 50A among the through holes 56 of the second through-hole group 53b located next to the first through-hole group 53a. The through hole 56B2 is the through hole 56 located closest to the first side edge 501 and farthest from the first portion 50A among the through holes 56 of the second through-hole group 53b located next to the first through-hole group 53a.

As illustrated in FIG. 7B, a first angle θ1 formed by the first array direction and the second array direction is an angle formed by the straight line L1 and the straight line L2. In the example illustrated in FIGS. 7A and 7B, the first array direction indicated by the straight line L1 is shifted clockwise with respect to the second array direction indicated by the straight line L2. As illustrated in FIG. 7C, the first array direction indicated by the straight line L1 may be shifted counterclockwise with respect to the second array direction indicated by the straight line L2.

The first angle θ1 is produced due to the fact that a forming step of the first portion 50A and a forming step of the second portion 50B are different steps. For example, the first angle θ1 is produced due to the fact that the first exposure mask used for forming the first portion 50A and the second exposure mask used for forming the second portion 50B are different from each other. When the direction of a side of the second exposure mask in relation to the direction of a side of the first exposure mask deviates from its ideal direction, the first angle θ1 is produced in accordance with an amount of this deviation.

The first angle θ1 may be, for example, 0.00021° or greater, 0.00042° or greater, 0.00063° or greater, or 0.00084° or greater. The first angle θ1 may be, for example, 0.00105° or less, 0.00125° or less, 0.00167° or less, or 0.00209° or less. The range of the first angle θ1 be determined based on a first group consisting of 0.00021°, 0.00042°, 0.00063°, and 0.00084° and/or a second group consisting of 0.00105°, 0.00125°, 0.00167°, and 0.00209°. The range of the first angle θ1 may be determined based on a combination of any one of the values included in the first group mentioned above and any one of the values included in the second group mentioned above. The range of the first angle θ1 may be determined based on a combination of any two of the values included in the first group mentioned above. The range of the first angle θ1 may be determined based on a combination of any two of the values included in the second group mentioned above. The first angle θ1 may be, for example, 0.00021° or greater and 0.00209° or less, 0.00021° or greater and 0.00167° or less, 0.00021° or greater and 0.00125° or less, 0.00021° or greater and 0.00105° or less, 0.00021° or greater and 0.00084° or less, 0.00021° or greater and 0.00063° or less, 0.00021° or greater and 0.00042° or less, 0.00042° or greater and 0.00209° or less, 0.00042° or greater and 0.00167° or less, 0.00042° or greater and 0.00125° or less, 0.00042° or greater and 0.00105° or less, 0.00042° or greater and 0.00084° or less, 0.00042° or greater and 0.00063° or less, 0.00063° or greater and 0.00209° or less, 0.00063° or greater and 0.00167° or less, 0.00063° or greater and 0.00125° or less, 0.00063° or greater and 0.00105° or less, 0.00063° or greater and 0.00084° or less, 0.00084° or greater and 0.00209° or less, 0.00084° or greater and 0.00167° or less, 0.00084° or greater and 0.00125° or less, 0.00084° or greater and 0.00105° or less, 0.00105° or greater and 0.00209° or less, 0.00105° or greater and 0.00167° or less, 0.00105° or greater and 0.00125° or less, 0.00125° or greater and 0.00209° or less, 0.00125° or greater and 0.00167° or less, or 0.00167° or greater and 0.00209° or less.

Even if tension is applied to the mask 50 in the first direction D1, an angular deviation between the first portion 50A and the second portion 50B such as the first angle θ1 is not perfectly eliminated, though there is a possibility of a reduction to some extent. Since the first angle θ1 is within the numerical range mentioned above, the present embodiment makes it possible to suppress PPA to a threshold value or less even in a case where the mask 50 has an angular deviation. PPA is an acronym for Pixel Position Accuracy. PPA corresponds to a distance between actual coordinates of a through hole 56 and ideal coordinates of the through hole 56.

The less the first angle θ1 is, the less PPA is. The first angle θ1 can be reduced by increasing the precision in adjustment of the position of the first exposure mask and the position of the second exposure mask. For example, in a case where the positions of the first exposure mask and the second exposure mask are adjusted using a driver, the precision in adjustment of the positions can be increased by making the minimum distance of movement by the driver shorter. However, the shorter the minimum distance of movement is, the longer the time taken for one adjustment is, resulting in lower productivity of the mask 50.

As shown in Examples to be described later, in a case where the first angle θ1 is within the numerical range mentioned above, PPA is suppressed to the threshold value or less. By not excessively aiming for a reduction in the first angle θ1, the present embodiment makes it possible to increase the productivity of the mask 50.

The threshold of PPA is determined depending on the distribution density of the through holes 56. The threshold of PPA is, for example, 5.0 μm, or may be 4.0 μm, 3.0 μm, 2.0 μm, or 1.0 μm.

The greater the first angle θ1 is, the poorer PPA is. The dimension S1 of the first step portion 501a mentioned above could also affect PPA. The first angle θ1 may be determined based on PPA and the dimension S1. For example, the following formula may hold between the first angle θ1 and the dimension S1: 4820[μm/°]×θ1[°]+S1[μm]≤Threshold×2[μm].

For example, when the threshold of PPA is 6.0 μm, the following formula may hold: 4820[μm/°]×θ1[°]+S1[μm]≤6.0[μm].

These formulas may be used when the dimension M12 of the middle portion 52 in the first direction D1 is 2200 mm or less.

A third array direction of the first through-hole group 53a and a fourth array direction of the second through-hole group 53b may form a second angle.

The third array direction is an array direction of through holes 56 belonging to the first through-hole group 53a located next to the second through-hole group 53b and arranged along the second side edge 502. The third array direction is indicated by a straight line L3 illustrated in FIG. 7A. The straight line L3 goes through a plurality of through holes 56 arranged along the second side edge 502 among those of the first through-hole group 53a. For example, the straight line L3 goes through a through hole 56A3 and a through hole 56A4. The through hole 56A3 is the through hole 56 located closest to the second side edge 502 and closest to the second portion 50B among the through holes 56 of the first through-hole group 53a located next to the second through-hole group 53b. The through hole 56A4 is the through hole 56 located closest to the second side edge 502 and farthest from the second portion 50B among the through holes 56 of the first through-hole group 53a located next to the second through-hole group 53b.

The fourth array direction is an array direction of through holes 56 belonging to the second through-hole group 53b located next to the first through-hole group 53a and arranged along the second side edge 502. The fourth array direction is indicated by a straight line L4 illustrated in FIG. 7A. The straight line L4 goes through a plurality of through holes 56 arranged along the second side edge 502 among those of the second through-hole group 53b. For example, the straight line L4 goes through a through hole 56B3 and a through hole 56B4. The through hole 56B3 is the through hole 56 located closest to the second side edge 502 and closest to the first portion 50A among the through holes 56 of the second through-hole group 53b located next to the first through-hole group 53a. The through hole 56B4 is the through hole 56 located closest to the second side edge 502 and farthest from the first portion 50A among the through holes 56 of the second through-hole group 53b located next to the first through-hole group 53a.

A second angle formed by the third array direction and the fourth array direction is an angle formed by the straight line L3 and the straight line L4. The above-described numerical range of the first angle θ1 can be adopted as the numerical range of the second angle.

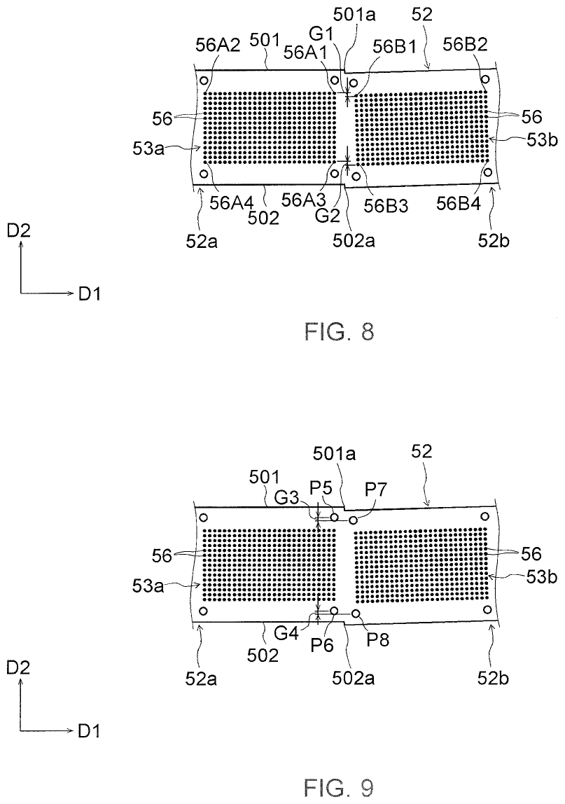

FIG. 8 is a plan view of an example of the first middle portion 52a and the second middle portion 52b. The reference sign G1 denotes a distance in the second direction D2 between the through hole 56A1 of the first through-hole group 53a and the through hole 56B1 of the second through-hole group 53b. The distance G1, similarly to the first step portion 501a, is produced due to the fact that a forming step of the first portion 50A and a forming step of the second portion 50B are different steps. The distance G1 may be, for example, 0.5 μm or longer, 1.0 μm or longer, or 2.0 μm or longer.

The boundary between the first portion 50A and the second portion 50B may be determined based on the distance G1. That is, the first through-hole group 53a and the second through-hole group 53b may be identified based on the distance G1. The above-described numerical range of the dimension S1 of the first step portion 501a can be adopted as the numerical range of the distance G1.

The reference sign G2 denotes a distance in the second direction D2 between the through hole 56A3 of the first through-hole group 53a and the through hole 56B3 of the second through-hole group 53b. The distance G2, similarly to the second step portion 502a, is produced due to the fact that a forming step of the first portion 50A and a forming step of the second portion 50B are different steps. The distance G2 may be, for example, 0.5 μm or longer, 1.0 μm or longer, or 2.0 μm or longer. The above-described numerical range of the dimension S1 of the first step portion 501a can be adopted as the numerical range of the distance G2.

As illustrated in FIG. 5, the middle portion 52 may include two or more first intermediate marks 58a arranged along the first side edge 501. In the method of manufacturing the mask 50, the positions of the first intermediate marks 58a are determined simultaneously with the position of the peripheral edge of the middle portion 52. For example, the positions of the first intermediate marks 58a located in the first portion 50A are determined simultaneously with the position of the peripheral edge of the first middle portion 52a. For example, the positions of the first intermediate marks 58a located in the second portion 50B are determined simultaneously with the position of the peripheral edge of the second middle portion 52b. The meaning of “the positions of two components are determined simultaneously” is that a resist layer corresponding to two components are exposed simultaneously by means of the same exposure mask.

The first intermediate mark 58a is, for example, a recess formed in the first surface 551, or a recess formed in the second surface 552. The depth of the recess may be, for example, 2 μm or greater, 3 μm or greater, or 5 μm or greater. The depth of the recess may be, for example, 10 μm or less, 20 μm or less, or 30 μm or less. The range of the depth of the recess may be determined based on a first group consisting of 2 μm, 3 μm, and 5 μm and/or a second group consisting of 10 μm, 20 μm, and 30 μm. The range of the depth of the recess may be determined based on a combination of any one of the values included in the first group mentioned above and any one of the values included in the second group mentioned above. The range of the depth of the recess may be determined based on a combination of any two of the values included in the first group mentioned above. The range of the depth of the recess may be determined based on a combination of any two of the values included in the second group mentioned above. For example, the depth of the recess may be 2 μm or greater and 30 μm or less, 2 μm or greater and 20 μm or less, 2 μm or greater and 10 μm or less, 2 μm or greater and 5 μm or less, 2 μm or greater and 3 μm or less, 3 μm or greater and 30 μm or less, 3 μm or greater and 20 μm or less, 3 μm or greater and 10 μm or less, 3 μm or greater and 5 μm or less, 5 μm or greater and 30 μm or less, 5 μm or greater and 20 μm or less, 5 μm or greater and 10 μm or less, 10 μm or greater and 30 μm or less, 10 μm or greater and 20 μm or less, or 20 μm or greater and 30 μm or less.

The first intermediate mark 58a may be a through hole going from the first surface 551 to the second surface 552.

The dimension of the first intermediate mark 58a in a plan view may be greater than the dimension r of a going-through portion 564 of the through hole 56. The ratio of the dimension of a first mark 58c in a plan view to the dimension r of the going-through portion 564 may be, for example, 1.03 or higher, 2.0 or higher, or 5.0 or higher. The ratio of the dimension of the first intermediate mark 58a in a plan view to the dimension r of the going-through portion 564 may be, for example, 5.0 or lower, 10 or lower, or 50 or lower. The range of the ratio of the dimension of the first intermediate mark 58a in a plan view to the dimension r of the going-through portion 564 may be determined based on a first group consisting of 1.03, 2.0, and 5.0 and/or a second group consisting of 5.0, 10, and 50. The range of the ratio of the dimension of the first intermediate mark 58a in a plan view to the dimension r of the going-through portion 564 may be determined based on a combination of any one of the values included in the first group mentioned above and any one of the values included in the second group mentioned above. The range of the ratio of the dimension of the first intermediate mark 58a in a plan view to the dimension r of the going-through portion 564 may be determined based on a combination of any two of the values included in the first group mentioned above. The range of the ratio of the dimension of the first intermediate mark 58a in a plan view to the dimension r of the going-through portion 564 may be determined based on a combination of any two of the values included in the second group mentioned above. For example, the ratio of the dimension of the first intermediate mark 58a in a plan view to the dimension r of the going-through portion 564 may be 1.03 or higher and 50 or lower, 1.03 or higher and 10 or lower, 1.03 or higher and 5.0 or lower, 1.03 or higher and 2.0 or lower, 2.0 or higher and 50 or lower, 2.0 or higher and 10 or lower, 2.0 or higher and 5.0 or lower, 5.0 or higher and 50 or lower, 5.0 or higher and 10 or lower, or 10 or higher and 50 or lower.

As illustrated in FIG. 5, the first end portion 51a may include the first mark 58c. The first mark 58c of the first end portion 51a may overlap with the first intermediate marks 58a of the first portion 50A when the mask 50 is viewed in the first direction D1.

As illustrated in FIG. 5, the second end portion 51b may include the first mark 58c. The first mark 58c of the second end portion 51b may overlap with the first intermediate marks 58a of the second portion 50B when the mask 50 is viewed in the first direction D1.

Similarly to the first intermediate mark 58a, the first mark 58c may be a recess formed in the first surface 551, a recess formed in the second surface 552, or a through hole.

As illustrated in FIG. 5, the middle portion 52 may include two or more second intermediate marks 58b arranged along the second side edge 502. In the method of manufacturing the mask 50, the positions of the second intermediate marks 58b are determined simultaneously with the position of the peripheral edge of the middle portion 52. For example, the positions of the second intermediate marks 58b located in the first portion 50A are determined simultaneously with the position of the peripheral edge of the first middle portion 52a. For example, the positions of the second intermediate marks 58b located in the second portion 50B are determined simultaneously with the position of the peripheral edge of the second middle portion 52b.

As illustrated in FIG. 5, the first end portion 51a may include a second mark 58d. The second mark 58d of the first end portion 51a may overlap with the second intermediate marks 58b of the first portion 50A when the mask 50 is viewed in the first direction D1.

As illustrated in FIG. 5, the second end portion 51b may include a second mark 58d. The second mark 58d of the second end portion 51b may overlap with the second intermediate marks 58b of the second portion 50B when the mask 50 is viewed in the first direction D1.

Similarly to the first intermediate mark 58a, the second intermediate mark 58b and the second mark 58d may be recesses formed in the first surface 551, recesses formed in the second surface 552, or through holes.

FIG. 9 is a plan view of an example of the first middle portion 52a and the second middle portion 52b. The reference sign G3 denotes a distance in the second direction D2 between a fifth reference point P5 and a seventh reference point P7. The fifth reference point P5 corresponds to the position of the first intermediate mark 58a located closest to the second portion 50B among the first intermediate marks 58a located in the first portion 50A. The seventh reference point P7 corresponds to the position of the first intermediate mark 58a located closest to the first portion 50A among the first intermediate marks 58a located in the second portion 50B. The distance G3, similarly to the first step portion 501a, is produced due to the fact that a forming step of the first portion 50A and a forming step of the second portion 50B are different steps. The distance G3 may be, for example, 0.5 μm or longer, 1.0 μm or longer, or 2.0 μm or longer.

The boundary between the first portion 50A and the second portion 50B may be determined based on the distance G3. That is, the boundary between the first portion 50A and the second portion 50B may be determined between two first intermediate marks 58a between which there is the distance G3. The above-described numerical range of the dimension S1 of the first step portion 501a can be adopted as the numerical range of the distance G3.

The reference sign G4 denotes a distance in the second direction D2 between a sixth reference point P6 and an eighth reference point P8. The sixth reference point P6 corresponds to the position of the second intermediate mark 58b located closest to the second portion 50B among the second intermediate marks 58b located in the first portion 50A. The eighth reference point P8 corresponds to the position of the second intermediate mark 58b located closest to the first portion 50A among the second intermediate marks 58b located in the second portion 50B. The distance G4, similarly to the second step portion 502a, is produced due to the fact that a forming step of the first portion 50A and a forming step of the second portion 50B are different steps. The distance G4 may be, for example, 0.5 μm or longer, 1.0 μm or longer, or 2.0 μm or longer. The above-described numerical range of the dimension S1 of the first step portion 501a can be adopted as the numerical range of the distance G4.

The positions of the through holes 56, the first side edge 501, the second side edge 502, the first end 503, and the second end 504 are measured by capturing an image of the mask 50 in a plan view and analyzing the image. The capturing is performed by utilizing light passing through the through holes 56 and light passing around the peripheral edges of the mask 50 along the direction of a line normal to the first surface 551. As the measurement equipment, AMIC-2500 manufactured by Sinto S-Precision, Ltd. is used.

In a case where the marks 58a to 58d are through holes, the positions of the marks 58a to 58d are measured based on an image captured using light passing through the marks 58a to 58d. As the measurement equipment, AMIC-2500 manufactured by Sinto S-Precision, Ltd. is used.

In a case where the marks 58a to 58d are recesses not going through a base material 55, the positions of the marks 58a to 58d are measured based on an image captured using light reflected by the mask 50.

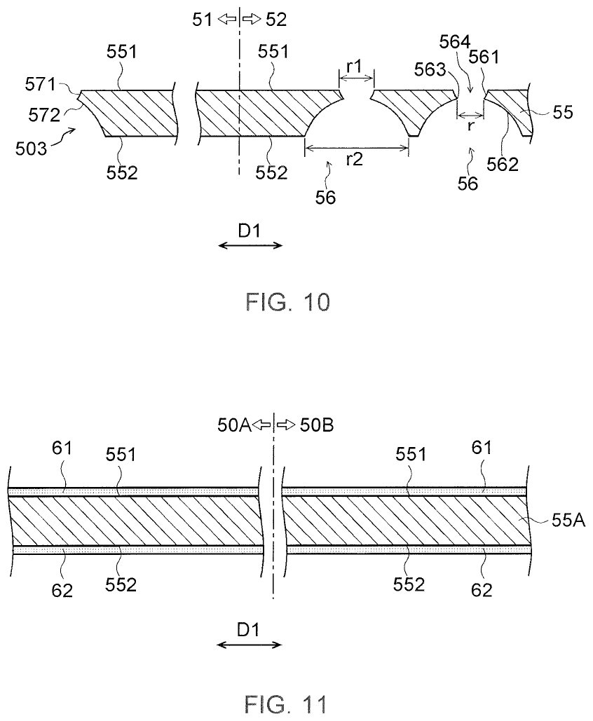

Next, a cross-sectional structure of the mask 50 will now be described. FIG. 10 is a cross-sectional view, viewed in a direction A-A, of the mask 50 illustrated in FIG. 5.

The mask 50 includes the base material 55 and the through holes 56 going through the base material 55. The base material 55 includes the first surface 551 and the second surface 552. The through holes 56 go through the base material 55 from the first surface 551 to the second surface 552.

The through hole 56 may include a first concave portion 561, a second concave portion 562, and a connection portion 563 connecting the first concave portion 561 and the second concave portion 562. The first concave portion 561 is a recess located in the first surface 551 and recessed toward the second surface 552. The second concave portion 562 is a recess located in the second surface 552 and recessed toward the first surface 551. Connection of the first concave portion 561 and the second concave portion 562 configures the through hole 56 going through the base material 55. The first concave portion 561 is formed by processing the base material 55 from the first surface 551 side by means of etching, laser, or the like. The second concave portion 562 is formed by processing the base material 55 from the second surface 552 side by means of etching, laser, or the like.

The first concave portion 561 has a dimension r1 in a plan view. The second concave portion 562 has a dimension r2 in a plan view. The dimension r2 may be greater than the dimension r1. For example, the contour of the second concave portion 562 may surround the contour of the first concave portion 561 in a plan view.

The connection portion 563 may have a contour that is continuous therearound. The connection portion 563 may be located between the first surface 551 and the second surface 552. The connection portion 563 may form the going-through portion 564 where the area size of the opening of the through hole 56 in a plan view of the mask 50 is the smallest.

The dimension r of the going-through portion 564 may be, for example, 10 μm or greater, 15 μm or greater, 20 μm or greater, or 25 μm or greater. The dimension r of the going-through portion 564 may be, for example, 40 μm or less, 45 μm or less, 50 μm or less, or 55 μm or less. The range of the dimension r of the going-through portion 564 may be determined based on a first group consisting of 10 μm, 15 μm, 20 μm, and 25 μm and/or a second group consisting of 40 μm, 45 μm, 50 μm, and 55 μm. The range of the dimension r of the going-through portion 564 may be determined based on a combination of any one of the values included in the first group mentioned above and any one of the values included in the second group mentioned above. The range of the dimension r of the going-through portion 564 may be determined based on a combination of any two of the values included in the first group mentioned above. The range of the dimension r of the going-through portion 564 may be determined based on a combination of any two of the values included in the second group mentioned above. For example, the dimension r of the going-through portion 564 may be 10 μm or greater and 55 μm or less, 10 μm or greater and 50 μm or less, 10 μm or greater and 45 μm or less, 10 μm or greater and 40 μm or less, 10 μm or greater and 25 μm or less, 10 μm or greater and 20 μm or less, 10 μm or greater and 15 μm or less, 15 μm or greater and 55 μm or less, 15 μm or greater and 50 μm or less, 15 μm or greater and 45 μm or less, 15 μm or greater and 40 μm or less, 15 μm or greater and 25 μm or less, 15 μm or greater and 20 μm or less, 20 μm or greater and 55 μm or less, 20 μm or greater and 50 μm or less, 20 μm or greater and 45 μm or less, 20 μm or greater and 40 μm or less, 20 μm or greater and 25 μm or less, 25 μm or greater and 55 μm or less, 25 μm or greater and 50 μm or less, 25 μm or greater and 45 μm or less, 25 μm or greater and 40 μm or less, 40 μm or greater and 55 μm or less, 40 μm or greater and 50 μm or less, 40 μm or greater and 45 μm or less, 45 μm or greater and 55 μm or less, 45 μm or greater and 50 μm or less, or 50 μm or greater and 55 μm or less.

The dimension r of the going-through portion 564 can be defined by light passing through the through hole 56. For example, parallel light is directed to enter either the first surface 551 or the second surface 552 of the mask 50 in the direction of a line normal to the mask 50, pass through the through holes 56, and then go out from the other of the first surface 551 and the second surface 552. The size of the area occupied by the outgoing light in the plane direction of the mask 50 is taken as the dimension r of the going-through portion 564.

In FIG. 10, an example in which the second surface 552 of the base material 55 is left between two second concave portions 562 located next to each other is illustrated, but without any limitation thereto. Though not illustrated, etching may be performed such that two second concave portions 562 located next to each other are continuous. That is, a region where the second surface 552 of the base material 55 is not left between two second concave portions 562 located next to each other may exist.

As illustrated in FIG. 10, the first end 503 may include recesses formed in the surfaces of the base material 55, similarly to the through hole 56. In the example illustrated in FIG. 10, the first end 503 includes a third concave portion 571, which is located in the first surface 551, and a fourth concave portion 572, which is located in the second surface 552. The third concave portion 571 and the fourth concave portion 572 are formed by processing the base material 55 by means of etching, laser, or the like, similarly to the first concave portion 561 and the second concave portion 562.

Though not illustrated, the first end 503 does not necessarily have to include the third concave portion 571 located in the first surface 551, though it includes the fourth concave portion 572 located in the second surface 552. In this case, the first end 503 is formed by processing the base material 55 by means of etching or the like from the second surface 552 side such that the fourth concave portion 572 reaches the first surface 551.

Though not illustrated, other edges/ends such as the first side edge 501, the second side edge 502, and the second end 504 may also include recesses formed in the surfaces of the base material 55, similarly to the first end 503.

The material of the mask 50 and the frame 41 will now be described. A ferrous alloy containing nickel can be used as the main material of the mask 50 and the frame 41. For example, a ferrous alloy whose nickel content in total is 28% by mass or more and 54% by mass or less can be used as the material of the base material 55 of the mask 50. This makes it possible to reduce a difference between a coefficient of thermal expansion of the mask 50 and the frame 41 and a coefficient of thermal expansion of the substrate 110 containing glass. This makes it possible to suppress a decrease in dimension precision and position precision of a vapor deposition layer formed on the substrate 110 due to thermal expansion of the mask 50, the frame 41, the substrate 110, and the like.

The ferrous alloy may contain cobalt in addition to nickel. For example, a ferrous alloy whose content of nickel and cobalt in total is 28% by mass or more and 54% by mass or less and whose cobalt content is 0% by mass or more and 6% by mass or less can be used as the material of the base material 55 of the mask 50.

The content of nickel in the base material 55 may be 28% by mass or more and 38% by mass or less. The content of nickel and cobalt in total in the base material 55 may be 28% by mass or more and 38% by mass or less. In this case, specific examples of the ferrous alloy containing nickel, or nickel and cobalt, are: an invar material, a super-invar material, an ultra-invar material, and the like. An invar material is a ferrous alloy containing 34% by mass or more and 38% by mass or less of nickel, the balance being iron and unavoidable impurities. A super-invar material is a ferrous alloy containing 30% by mass or more and 34% by mass or less of nickel, and cobalt, the balance being iron and unavoidable impurities. An ultra-invar material is a ferrous alloy containing 28% by mass or more and 34% by mass or less of nickel, 2% by mass or more and 7% by mass or less of cobalt, 0.1% by mass or more and 1.0% by mass or less of manganese, 0.10% by mass or less of silicon, and 0.01% by mass or less of carbon, the balance being iron and unavoidable impurities.

The content of nickel and cobalt in total in the mask 50 may be 38% by mass or more and 54% by mass or less. For example, the mask 50 may be made of a ferrous alloy containing 38% by mass or more and 54% by mass or less of nickel, the balance being iron and unavoidable impurities. The mask 50 having such a composition may be manufactured using a plating method.

In a case where the temperature of the mask 50, the frame 41, and the substrate 110 do not reach a high temperature during the vapor deposition processing, there is no need to care about the difference between the coefficient of thermal expansion of the mask 50 and the frame 41 and the coefficient of thermal expansion of the substrate 110. In this case, a material other than the ferrous alloy mentioned above may be used as the material of the mask 50. For example, a ferrous alloy other than the nickel-containing ferrous alloy mentioned above, such as a ferrous alloy containing chromium, may be used. As the ferrous alloy containing chromium, for example, a so-called stainless ferrous alloy can be used. An alloy other than a ferrous alloy, such as a nickel alloy or a nickel-cobalt alloy, may be used.

The thickness T of the mask 50 may be, for example, 10 μm or greater, 15 μm or greater, 20 μm or greater, or 30 μm or greater. The thickness T may be, for example, 35 μm or less, 50 μm or less, 80 μm or less, or 100 μm or less. The range of the thickness T may be determined based on a first group consisting of 10 μm, 15 μm, 20 μm, and 30 μm and/or a second group consisting of 35 μm, 50 μm, 80 μm, and 100 μm. The range of the thickness T may be determined based on a combination of any one of the values included in the first group mentioned above and any one of the values included in the second group mentioned above. The range of the thickness T may be determined based on a combination of any two of the values included in the first group mentioned above. The range of the thickness T may be determined based on a combination of any two of the values included in the second group mentioned above. The thickness T may be, for example, 10 μm or greater and 100 μm or less, 10 μm or greater and 80 μm or less, 10 μm or greater and 50 μm or less, 10 μm or greater and 35 μm or less, 10 μm or greater and 30 μm or less, 10 μm or greater and 20 μm or less, 10 μm or greater and 15 μm or less, 15 μm or greater and 100 μm or less, 15 μm or greater and 80 μm or less, 15 μm or greater and 50 μm or less, 15 μm or greater and 35 μm or less, 15 μm or greater and 30 μm or less, 15 μm or greater and 20 μm or less, 20 μm or greater and 100 μm or less, 20 μm or greater and 80 μm or less, 20 μm or greater and 50 μm or less, 20 μm or greater and 35 μm or less, 20 μm or greater and 30 μm or less, 30 μm or greater and 100 μm or less, 30 μm or greater and 80 μm or less, 30 μm or greater and 50 μm or less, 30 μm or greater and 35 μm or less, 35 μm or greater and 100 μm or less, 35 μm or greater and 80 μm or less, 35 μm or greater and 50 μm or less, 50 μm or greater and 100 μm or less, 50 μm or greater and 80 μm or less, or 80 μm or greater and 100 μm or less.

The greater the thickness T of the mask 50 is, the higher the rigidity of the mask 50 is. Configuring the rigidity of the mask 50 to be high makes it possible to suppress a significant deformation of the mask 50 from occurring locally in the neighborhood of the first step portion 501a or the second step portion 502a when tension is applied to the mask 50 in the first direction D1. This makes it possible to suppress a deviation in the positions the through holes 56 of the through-hole group 53 near the first step portion 501a or the second step portion 502a from their ideal positions.

The less the thickness T of the mask 50 is, the lower the ratio of the vapor deposition material 7 that gets caught on the wall surface of the through holes 56 before passing through the through holes 56 is. This makes it possible to increase the use efficiency of the vapor deposition material 7.

A contact-type measurement method is adopted as the method for measuring the thickness T. A length gauge “MT1271” in HEIDENHAIN-METRO series manufactured by Heidenhain GmbH and having a guide-ball-bushing-type plunger is used for the contact-type measurement.

Next, a method of manufacturing the mask 50 will now be described. First, a base material is prepared. The base material may be prepared in the form of a roll of a base material to be extended in the first direction D1. In this case, the base material unreeled from the roll is transported toward an exposure apparatus, a development apparatus, an etching apparatus, and the like. The base material is transported intermittently each time processing finishes at the exposure apparatus, the development apparatus, the etching apparatus, and the like.

Next, the mask 50 is manufactured by processing the base material. A plurality of masks 50 is manufactured from a single base material. For example, a plurality of masks 50 is manufactured from a roll of a base material. In the description below, the base material used for manufacturing the mask 50 will be referred to as “original base material” and denoted as 55A.

The method of manufacturing the mask 50 includes a first portion forming step and a second portion forming step. In the first portion forming step, the first through-hole groups 53a, the peripheral edges of the first middle portion 52a, and the peripheral edges of the first end portion 51a are formed in the original base material 55A. In the first portion forming step, the intermediate marks 58a and 58b of the first middle portion 52a and the marks 58c and 58d of the first end portion 51a may be formed in the original base material 55A. In the second portion forming step, the second through-hole groups 53b, the peripheral edges of the second middle portion 52b, and the peripheral edges of the second end portion 51b are formed in the original base material 55A. In the second portion forming step, the intermediate marks 58a and 58b of the second middle portion 52b and the marks 58c and 58d of the second end portion 51b may be formed in the original base material 55A.

The first portion forming step includes a resist layer forming process, a first exposure process, a development process, an etching process, and a resist removal process.

The second portion forming step includes a resist layer forming process, a second exposure process, a development process, an etching process, and a resist removal process.

The resist layer forming process, the development process, the etching process, and the resist removal process may be processes that are common to the first portion forming step and the second portion forming step. For example, in the resist layer forming process, a resist layer may be formed simultaneously at, of the original base material 55A, an area corresponding to the first portion 50A and an area corresponding to the second portion 50B. That is, the resist layer forming process of the first portion forming step and the resist layer forming process of the second portion forming step may be executed simultaneously. In the development process, the etching process, and the resist removal process, the resist layer located at, of the original base material 55A, the area corresponding to the first portion 50A and the area corresponding to the second portion 50B may be processed simultaneously. That is, the development process of the first portion forming step and the development process of the second portion forming step may be executed simultaneously. In addition, the etching process of the first portion forming step and the etching process of the second portion forming step may be executed simultaneously. In addition, the resist removal process of the first portion forming step and the resist removal process of the second portion forming step may be executed simultaneously.

The second exposure process of the second portion forming step is executed at a point in time different from that of the first exposure process of the first portion forming step.

After the preparation of the original base material 55A, the resist layer forming process is executed. In the resist layer forming process, as illustrated in FIG. 11, a resist layer is provided on the surface of the original base material 55A. As a result, a laminated body that includes the original base material 55A and the resist layer is obtained. The resist layer may include a first resist layer 61 located on the first surface 551 and a second resist layer 62 located on the second surface 552.

The resist layer may be a layer formed by applying a solution that contains a resist material to the surface of the original base material 55A and then solidifying it. Alternatively, the resist layer may be a layer formed by sticking a film such as a dry film to the surface of the original base material 55A.

The applying-type resist layer is formed by applying a solution that contains a photosensitive material to the surface of the original base material 55A and then solidifying it. When this is performed, a resist layer baking process of baking the resist layer may be executed. The photosensitive material may be a photo-dissolution-type material, a so-called positive-type material, or, alternatively, a photo-curing-type material, a so-called negative-type material.

An example of the positive-type photosensitive material is a novolac-based positive resist such as SC500. An example of the negative-type photosensitive material is a casein resist.

The thickness of the resist layer may be, for example, 1 μm or greater, 2 μm or greater, or 3 μm or greater. The thickness of the resist layer may be, for example, 5 μm or less, 7 μm or less, or 10 μm or less. The range of the thickness of the resist layer may be determined based on a first group consisting of 1 μm, 2 μm, and 3 μm and/or a second group consisting of 5 μm, 7 μm, and 10 μm. The range of the thickness of the resist layer may be determined based on a combination of any one of the values included in the first group mentioned above and any one of the values included in the second group mentioned above. The range of the thickness of the resist layer may be determined based on a combination of any two of the values included in the first group mentioned above. The range of the thickness of the resist layer may be determined based on a combination of any two of the values included in the second group mentioned above. For example, the thickness of the resist layer may be 1 μm or greater and 10 μm or less, 1 μm or greater and 7 μm or less, 1 μm or greater and 5 μm or less, 1 μm or greater and 3 μm or less, 1 μm or greater and 2 μm or less, 2 μm or greater and 10 μm or less, 2 μm or greater and 7 μm or less, 2 μm or greater and 5 μm or less, 2 μm or greater and 3 μm or less, 3 μm or greater and 10 μm or less, 3 μm or greater and 7 μm or less, 3 μm or greater and 5 μm or less, 5 μm or greater and 10 μm or less, 5 μm or greater and 7 μm or less, or 7 μm or greater and 10 μm or less.

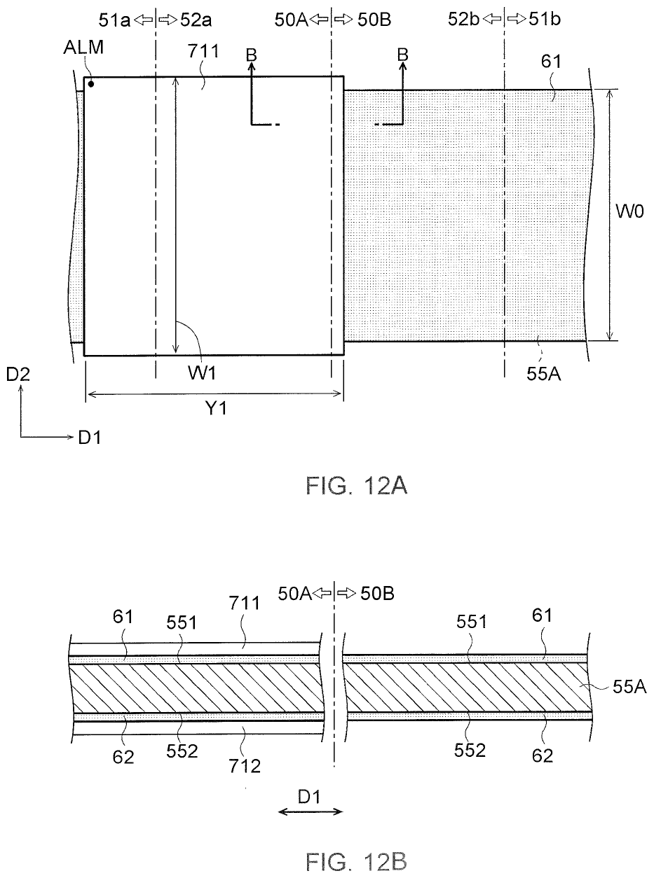

Next, the first exposure process is executed. In the first exposure process, as illustrated in FIGS. 12A and 12B, the resist layer on the original base material 55A is exposed using the first exposure mask. The first exposure mask is used for exposing the resist layer located at an area corresponding to the first middle portion 52a and the first end portion 51a. That is, the first exposure mask is used for exposing the resist layer corresponding to the first portion 50A. The first exposure mask may include a first surface first exposure mask 711, through which the first resist layer 61 is exposed, and a second surface first exposure mask 712, through which the second resist layer 62 is exposed.

As illustrated in FIG. 12A, the first exposure mask may have a quadrangular shape that includes a first side and a second side. The first side may extend in a direction in which the original base material 55A is transported. The second side may extend in a direction orthogonal to the direction in which the original base material 55A is transported. The dimension of the first side will be referred to also as “length” and denoted as Y1. The dimension of the second side will be referred to also as “width” and denoted as W1. The direction in which the original base material 55A is transported may be parallel to the first direction D1 of the mask 50.

The width W1 of the first exposure mask may be greater than the width W0 of the original base material 55A. The width W0 is the dimension of the original base material 55A in the direction orthogonal to the direction in which the original base material 55A is transported.

The width W0 may be, for example, 100 mm or greater, 200 mm or greater, or 400 mm or greater. The width W0 may be, for example, 600 mm or less, 800 mm or less, or 1000 mm or less. The range of the width W0 may be determined based on a first group consisting of 100 mm, 200 mm, and 400 mm and/or a second group consisting of 600 mm, 800 mm, and 1000 mm. The range of the width W0 may be determined based on a combination of any one of the values included in the first group mentioned above and any one of the values included in the second group mentioned above. The range of the width W0 may be determined based on a combination of any two of the values included in the first group mentioned above. The range of the width W0 may be determined based on a combination of any two of the values included in the second group mentioned above. For example, the width W0 may be 100 mm or greater and 1000 mm or less, 100 mm or greater and 800 mm or less, 100 mm or greater and 600 mm or less, 100 mm or greater and 400 mm or less, 100 mm or greater and 200 mm or less, 200 mm or greater and 1000 mm or less, 200 mm or greater and 800 mm or less, 200 mm or greater and 600 mm or less, 200 mm or greater and 400 mm or less, 400 mm or greater and 1000 mm or less, 400 mm or greater and 800 mm or less, 400 mm or greater and 600 mm or less, 600 mm or greater and 1000 mm or less, 600 mm or greater and 800 mm or less, or 800 mm or greater and 1000 mm or less.

The width W1 of the first exposure mask may be, for example, 400 mm or greater, 600 mm or greater, 810 mm or greater, or 1100 mm or greater. The width W1 may be, for example, 600 mm or less, 1000 mm or less, 1100 mm or less, or 1400 mm or less. The range of the width W1 may be determined based on a first group consisting of 400 mm, 600 mm, 810 mm, and 1100 mm and/or a second group consisting of 600 mm, 1000 mm, 1100 mm, and 1400 mm. The range of the width W1 may be determined based on a combination of any one of the values included in the first group mentioned above and any one of the values included in the second group mentioned above. The range of the width W1 may be determined based on a combination of any two of the values included in the first group mentioned above. The range of the width W1 may be determined based on a combination of any two of the values included in the second group mentioned above. For example, the width W1 may be 400 mm or greater and 1400 mm or less, 400 mm or greater and 1100 mm or less, 400 mm or greater and 1000 mm or less, 400 mm or greater and 810 mm or less, 400 mm or greater and 600 mm or less, 600 mm or greater and 1400 mm or less, 600 mm or greater and 1100 mm or less, 600 mm or greater and 1000 mm or less, 600 mm or greater and 810 mm or less, 810 mm or greater and 1400 mm or less, 810 mm or greater and 1100 mm or less, 810 mm or greater and 1000 mm or less, 1000 mm or greater and 1400 mm or less, 1000 mm or greater and 1100 mm or less, or 1100 mm or greater and 1400 mm or less.

The first exposure mask has the length Y1. The length Y1 is the dimension of the first exposure mask in the direction in which the original base material 55A is transported. The length Y1 may be greater than, or less than, the width W1. The length Y1 may be less than the dimension M11 of the mask 50. The length Y1 corresponds to the dimension M15 of the first portion 50A. The above-described numerical range of the dimension M15 can be adopted as the numerical range of the length Y1.

As illustrated in FIG. 12B, in the first exposure process, the first surface first exposure mask 711 may be disposed in such a way as to face the first resist layer 61, and, at the same time, the second surface first exposure mask 712 may be disposed in such a way as to face the second resist layer 62. The first exposure process may include a first position adjustment process for a relative position adjustment between the first surface first exposure mask 711 and the second surface first exposure mask 712. In the first position adjustment process, a position adjustment may be performed such that the alignment mark of the first surface first exposure mask 711 and the alignment mark of the second surface first exposure mask 712 overlap. Executing the first position adjustment process suppresses a deviation in position between the center of the first concave portion 561 and the center of the second concave portion 562 in a plan view.

As illustrated in FIG. 12A, the alignment mark ALM of the first surface first exposure mask 711 may be located at a position where it does not overlap with the original base material 55A in a plan view. Similarly, the alignment mark of the second surface first exposure mask 712 may also be located at a position where it does not overlap with the original base material 55A in a plan view. Though not illustrated, the first position adjustment process may be executed based on something other than the alignment marks. For example, the first position adjustment process may be executed based on the peripheral edge of the first surface first exposure mask 711 and the peripheral edge of the second surface first exposure mask 712.

In the first position adjustment process, the position of either one of the first surface first exposure mask 711 and the second surface first exposure mask 712 may be adjusted. In the first position adjustment process, the positions of both of the first surface first exposure mask 711 and the second surface first exposure mask 712 may be adjusted. In the first position adjustment process, the position adjustment may be performed by moving the first surface first exposure mask 711 and/or the second surface first exposure mask 712 with the use of a driver.

The first exposure process may include a first position recording process of recording the position of the first surface first exposure mask 711 and the position of the second surface first exposure mask 712. For example, the position of the first surface first exposure mask 711 and the position of the second surface first exposure mask 712 after the adjustment performed by executing the first position adjustment process may be recorded. The position recorded by executing the first position recording process will be referred to also as “first recording position”. The first recording position may be recorded as coordinates in a coordinate system on which the driver operates.

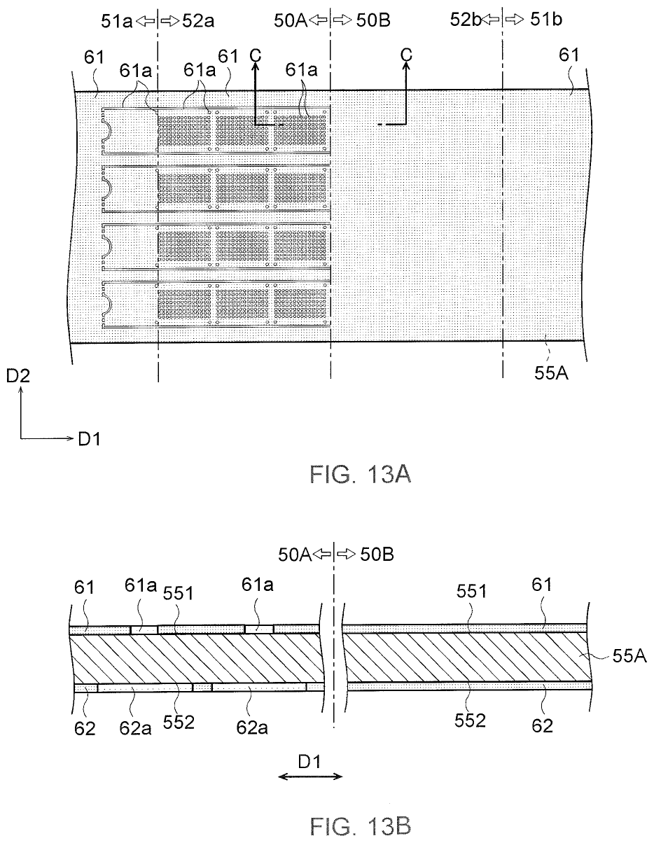

FIG. 13A is a plan view of an example of the resist layer exposed using the first exposure mask, and FIG. 13B is a cross-sectional view thereof. The exposed first resist layer 61 includes a first to-be-removed portion 61a. The first to-be-removed portion 61a is, of the first resist layer 61, a portion that is to be removed by being developed in the development process to be described later. In a state illustrated in FIGS. 13A and 13B, the first resist layer 61 has not been developed yet. In a case where the first resist layer 61 includes a positive-type photosensitive material, the portion irradiated with exposure light turns into the first to-be-removed portion 61a. In a case where the first resist layer 61 includes a negative-type photosensitive material, the portion not irradiated with exposure light turns into the first to-be-removed portion 61a and is removed in the development process to be described later.

Similarly to the first resist layer 61, the second resist layer 62 includes a second to-be-removed portion 62a. The second to-be-removed portion 62a is, of the second resist layer 62, a portion that is to be removed by being developed. In a case where the second resist layer 62 includes a positive-type photosensitive material, the portion irradiated with exposure light turns into the second to-be-removed portion 62a. In a case where the second resist layer 62 includes a negative-type photosensitive material, the portion not irradiated with exposure light turns into the second to-be-removed portion 62a and is removed in the development process.

As illustrated in FIG. 13A, the first to-be-removed portion 61a produced by executing the first exposure process is located at, of the first resist layer 61, the area corresponding to the peripheral edges of the first middle portion 52a, the peripheral edges of the first end portion 51a, the through holes 56, the intermediate marks 58a and 58b, and the marks 58c and 58d. Though not illustrated, similarly, the second to-be-removed portion 62a produced by executing the first exposure process is located at, of the second resist layer 62, the area corresponding to the peripheral edges of the first middle portion 52a, the peripheral edges of the first end portion 51a, the through holes 56, the intermediate marks 58a and 58b, and the marks 58c and 58d.

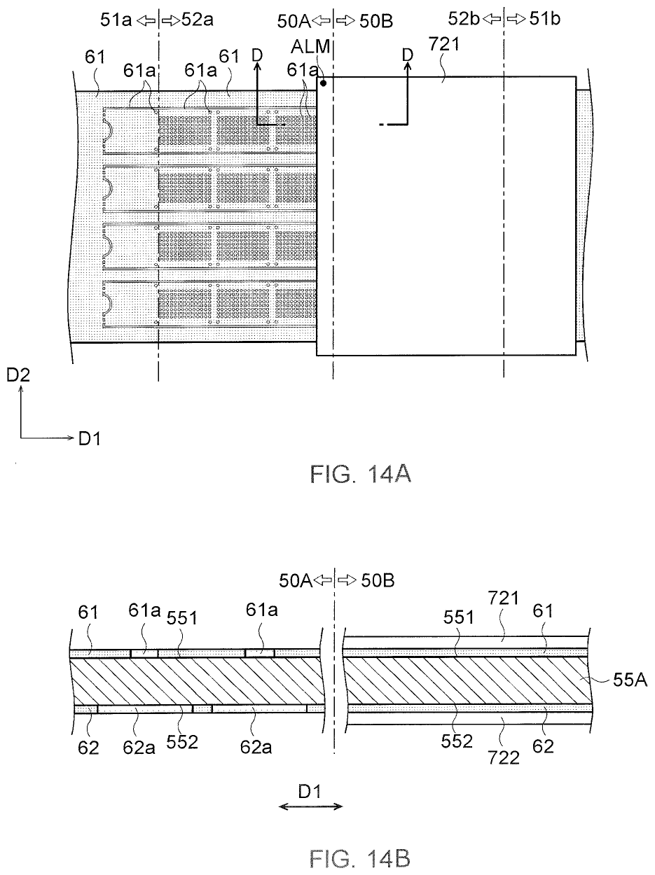

Next, the second exposure process is executed. In the second exposure process, as illustrated in FIGS. 14A and 14B, the resist layer on the original base material 55A is exposed using the second exposure mask. The second exposure mask is used for exposing the resist layer located at an area corresponding to the second middle portion 52b and the second end portion 51b. That is, the second exposure mask is used for exposing the resist layer corresponding to the second portion 50B. The second exposure mask may include a first surface second exposure mask 721, through which the first resist layer 61 is exposed, and a second surface second exposure mask 722, through which the second resist layer 62 is exposed.

In the second exposure process, the position alignment of the second exposure mask with respect to the original base material 55A may be performed by moving the second exposure mask with the use of a driver. The process of adjusting the position of the second exposure mask in the second exposure process will be referred to also as “second position adjustment process”. The driver is configured to be able to adjust the position of the exposure mask with high precision. For example, the driver may include a microactuator. The microactuator may include a static actuator, an electromagnetic actuator, a piezoelectric actuator, a thermal expansion actuator, or the like.

In the second position adjustment process, the position of the second exposure mask may be adjusted while taking, as a reference, the position of the first exposure mask having been used in the first exposure process. For example, the position of the second exposure mask may be adjusted while taking, as a reference, the first recording position of the first exposure mask having been recorded in the first position recording process. For example, the first surface second exposure mask 721 and/or the second surface second exposure mask 722 may be moved using the driver while taking, as a reference, the first recording position as coordinates in the coordinate system on which the driver operates.

Using the position of the first exposure mask as the reference makes it possible to suppress a deviation in the relative position of the second exposure mask in relation to the first exposure mask from its ideal position. For example, the second position adjustment process reduces the dimension S1 of the first step portion 501a described earlier. For example, the second position adjustment process reduces the first angle θ1 described earlier.

Adjusting the position of the second exposure mask while taking the position of the first exposure mask as the reference will be referred to also as “first-type adjustment”.

In the second position adjustment process, the position of the second exposure mask may be adjusted while taking, as a reference, the resist layer 61, 62 corresponding to the first portion 50A after the execution of the first exposure process. In this case, the resist layer 61, 62 corresponding to the first portion 50A after the execution of the first exposure process includes a portion that can be taken as the reference. The portion that can be taken as the reference will be referred to also as “reference portion”. The reference portion may be a part of the resist layer 61, 62 having been irradiated with exposure light in the first exposure process. The reference portion may be a part of the resist layer 61, 62 not having been irradiated with exposure light in the first exposure process.

The position of the reference portion of the resist layer 61, 62 reflects the position of the first exposure mask in the first exposure process. Similarly to the first-type adjustment described above, using the reference portion of the resist layer 61, 62 as the reference makes it possible to suppress a deviation in the relative position of the second exposure mask in relation to the first exposure mask from its ideal position.

Adjusting the position of the second exposure mask while taking the reference portion of the resist layer 61, 62 as the reference will be referred to also as “second-type adjustment”. In the second-type adjustment, the position of the first surface second exposure mask 721 may be adjusted while taking the reference portion of the first resist layer 61 as the reference. In the second-type adjustment, the position of the second surface second exposure mask 722 may be adjusted while taking the reference portion of the second resist layer 62 as the reference.

The reference portion of the resist layer 61, 62 may be formed at, of the resist layer 61, 62, an area not overlapping with the mask 50 in a plan view.

The reference portion of the resist layer 61, 62 may be formed in the resist layer 61, 62 by contact of a part of the first exposure mask in the first exposure process with the resist layer 61, 62. For example, the first exposure mask may include a projection protruding toward the resist layer 61, 62 in the thickness direction. In this case, the projection of the first exposure mask comes into contact with the resist layer 61, 62 in the first exposure process to deform a part of the resist layer 61, 62, thereby forming the reference portion in the resist layer 61, 62.

The reference portion of the resist layer 61, 62 may be formed in the resist layer 61, 62 by processing a part of the resist layer 61, 62 by means of laser light in the first exposure process. For example, the first exposure mask may include a transmissive portion through which laser light passes partially. For example, the first exposure mask may include a shield layer and an opening, the shield layer may be located at an area of not overlapping with the mask 50 in a plan view and configured to block laser light, and the opening may be formed in the shield layer. In this case, in the first exposure process, laser light may be emitted toward the transmissive portion of the first exposure mask. The laser light having passed through the opening of the transmissive portion of the first exposure mask reaches the resist layer 61, 62 in the first exposure process to process a part of the resist layer 61, 62, thereby forming the reference portion in the resist layer 61, 62.

In the second position adjustment process, a relative position adjustment between the first surface second exposure mask 721 and the second surface second exposure mask 722 may be performed. For example, in the second position adjustment process, a position adjustment may be performed such that the alignment mark of the first surface second exposure mask 721 and the alignment mark of the second surface second exposure mask 722 overlap. The relative position adjustment between the first surface second exposure mask 721 and the second surface second exposure mask 722 will be referred to also as “third-type adjustment”.

In the second position adjustment process, the above-described first-type adjustment, the above-described second-type adjustment, and the above-described third-type adjustment may be combined arbitrarily and executed. For example, the first-type adjustment or the second-type adjustment may be executed, and, in addition, the third-type adjustment may be executed.

For example, the position of the first surface second exposure mask 721 may be adjusted by the first-type adjustment or the second-type adjustment, and the relative position of the second surface second exposure mask 722 in relation to the first surface second exposure mask 721 may be thereafter adjusted by the third-type adjustment.

For example, the position of the second surface second exposure mask 722 may be adjusted by the first-type adjustment or the second-type adjustment, and the relative position of the first surface second exposure mask 721 in relation to the second surface second exposure mask 722 may be thereafter adjusted by the third-type adjustment.

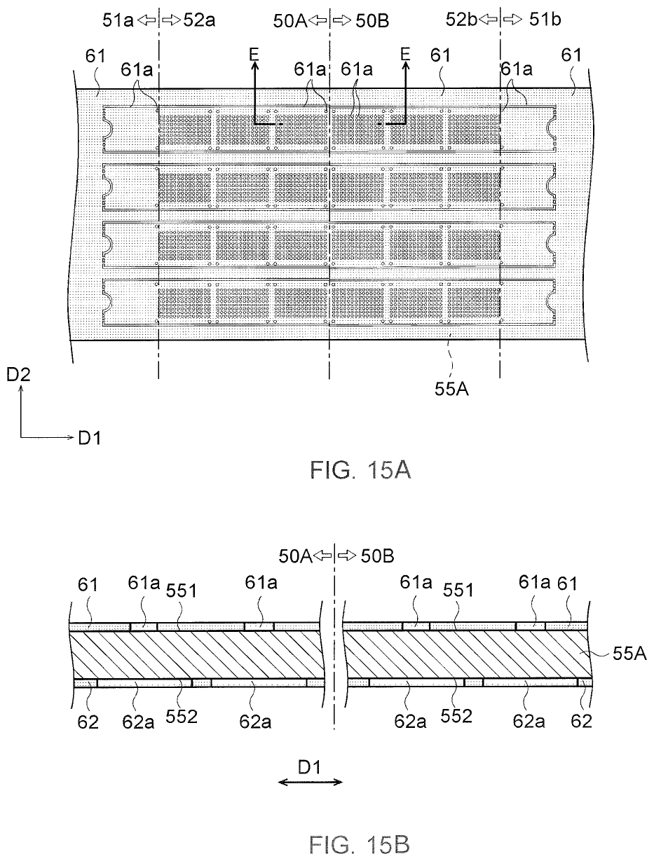

FIG. 15A is a plan view of an example of the resist layer exposed using the second exposure mask, and FIG. 15B is a cross-sectional view thereof.

As illustrated in FIG. 15A, the first to-be-removed portion 61a produced by executing the second exposure process is located at, of the first resist layer 61, the area corresponding to the peripheral edges of the second middle portion 52b, the peripheral edges of the second end portion 51b, the through holes 56, the intermediate marks 58a and 58b, and the marks 58c and 58d. Though not illustrated, the second to-be-removed portion 62a produced by executing the second exposure process is located at, of the second resist layer 62, the area corresponding to the peripheral edges of the second middle portion 52b, the peripheral edges of the second end portion 51b, the through holes 56, the intermediate marks 58a and 58b, and the marks 58c and 58d.

Next, the development process is executed. As a result, the first to-be-removed portion 61a and the second to-be-removed portion 62a are removed.

Next, the etching process is executed. In the etching process, the original base material 55A is etched using the first resist layer 61 and the second resist layer 62 that have been exposed and developed. The etching process may include a first surface etching process, in which the first surface 551 is etched, and a second surface etching process, in which the second surface 552 is etched. As an etchant, for example, a ferric chloride solution and a fluid containing hydrochloric acid can be used.

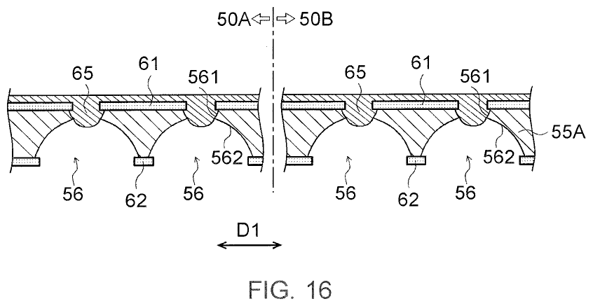

FIG. 16 is a cross-sectional view of an example of the etched original base material 55A. The first concave portion 561 and the non-illustrated third concave portion 571 are formed in the first surface 551 through the first surface etching process. The second concave portion 562 and the non-illustrated fourth concave portion 572 are formed in the second surface 552 through the second surface etching process. Connection of the first concave portion 561 and the second concave portion 562 configures the through hole 56. Connection of the third concave portion 571 and the fourth concave portion 572 configures a through hole. The through hole made up of the third concave portion 571 and the fourth concave portion 572 and defining the peripheral edge of the mask 50 will be referred to also as “peripheral edge cavity”. Though not illustrated, the first intermediate marks 58a, the second intermediate marks 58b, the first marks 58c, and the second marks 58d are also formed through the etching process.

As illustrated in FIG. 16, the first concave portion 561 and the non-illustrated third concave portion 571 may be filled with resin 65 after the first surface etching process but before the second surface etching process.

Next, the resist layer removal process is executed. As a result, the first resist layer 61 and the second resist layer 62 are removed. In addition, a process of removing the resin 65 is executed. The resin 65 may be removed simultaneously with the removal of the first resist layer 61 and the second resist layer 62.

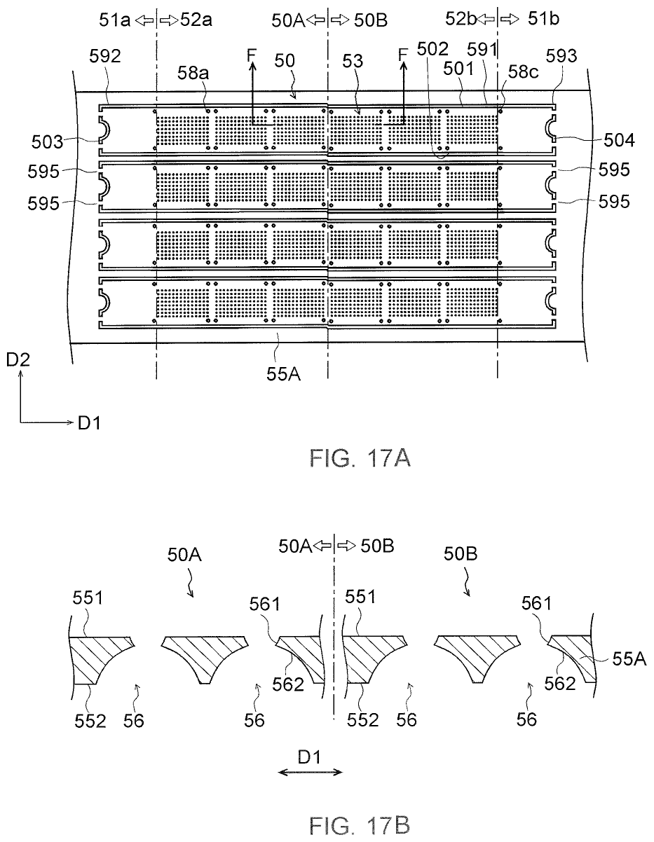

FIG. 17A is a plan view of the original base material 55A after the removal of the first resist layer 61 and the second resist layer 62, and FIG. 17B is a cross-sectional view thereof. The original base material 55A includes the through-hole groups 53 including the through holes 56, the peripheral edge cavities defining the peripheral edges of the mask 50, and the marks 58a, 58b, 58c, and 58d. The peripheral edge cavity defining the peripheral edge of the first end portion 51a will be referred to also as “second peripheral edge cavity” and denoted as 592. The peripheral edge cavity defining the peripheral edge of the middle portion 52 will be referred to also as “first peripheral edge cavity” and denoted as 591. The peripheral edge cavity defining the peripheral edge of the second end portion 51b will be referred to also as “third peripheral edge cavity” and denoted as 593.

As illustrated in FIG. 17A, bridges 595 may be connected to the peripheral edges of the mask 50. In the example illustrated in FIG. 17A, the bridges 595 are connected to the first end 503 and the second end 504.

The bridge 595 is, of the original base material 55A, a portion spanning across the peripheral edge cavity. The bridges 595 connect the peripheral edges of the mask 50 to the original base material 55A therearound. Providing the bridges 595 makes it possible to suppress the mask 50 from coming off from the original base material 55A. The mask 50 can be clipped out of the original base material 55A by breaking the bridges 595.

In the present embodiment, as described above, the resist layer corresponding to the first middle portion 52a of the middle portion 52 is exposed using the first exposure mask. In addition, the resist layer corresponding to the second middle portion 52b of the middle portion 52 is exposed using the second exposure mask different from the first exposure mask. Therefore, it is possible to make the dimension M12 of the middle portion 52 larger than in a case where the entire mask 50 is formed using a single exposure mask. For this reason, it is possible to increase the dimension M11 of the mask 50 while using exposure masks that are easily available. That is, it is possible to increase the dimension M11 of the mask 50 while suppressing an investment in the manufacturing facilities of the mask 50.

However, it could happen that the relative position of the second exposure mask in relation to the first exposure mask deviates from its ideal position. Therefore, it could happen that the first array direction of the through holes 56 of the first through-hole group 53a is not in alignment with the second array direction of the through holes 56 of the second through-hole group 53b.

The method of manufacturing the mask 50 may include a screening step of screening the mask 50 on the basis of the first angle θ1 described earlier. The first angle θ1 indicates a deviation of the first array direction with respect to the second array direction. In the screening step, for example, masks 50 having the first angle θ1 not greater than a threshold are selected as non-defective masks. The threshold may be, for example, 0.00042°, 0.00063°, 0.00084°, 0.00105°, 0.00125°, 0.00167°, or 0.00209°.

The method of manufacturing the mask 50 may include a screening step of screening the mask 50 on the basis of the dimension S1 of the first step portion 501a of the first side edge 501. The method of manufacturing the mask 50 may include a screening step of screening the mask 50 on the basis of the distance G1 described earlier. The method of manufacturing the mask 50 may include a screening step of screening the mask 50 on the basis of the distance G3 described earlier. In the screening step, for example, masks 50 having the dimension S1 or the distance G1 or the distance G3 not greater than a threshold are selected as non-defective masks. The threshold of the dimension S1 or the distance G1 or the distance G3 may be, for example, 0.1 μm, 0.2 μm, 0.5 μm, 1.0 μm, 1.5 μm, 2.0 μm, 2.5 μm, or 3.0 μm.

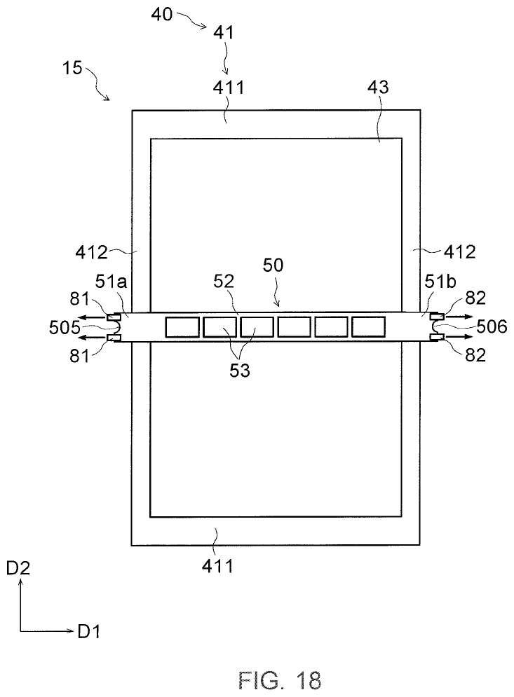

Next, a method of manufacturing the mask apparatus 15 will now be described. First, the frame 41 is prepared. Next, an alignment step of determining the position of the mask 50 in relation to the frame 41 is executed. In the alignment step, the position of the mask 50 may be determined while applying tension to the mask 50. For example, as illustrated in FIG. 18, tension may be applied to the mask 50 by using clamps. The clamps include, for example, a first clamp 81 attached to the first end portion 51a and a second clamp 82 attached to the second end portion 51b. The first clamp 81 is attached to, of the first end 503, a portion where no recess 505 is formed. For example, as illustrated in FIG. 18, in a case where the first end 503 has one recess 505, two first clamps 81 may be attached to, of the first end 503, the portion where no recess 505 is formed. In a case where the first end 503 has two or more recesses 505, three or more first clamps 81 may be attached to, of the first end 503, the portion where no recess 505 is formed.

The number of recesses 506 formed in the second end 504 may be the same as the number of the recesses 505 formed in the first end 503. The number of the second clamps 82 attached to the second end portion 51b may be the same as the number of the first clamps 81 attached to the first end portion 51a.

In the alignment step, the mask 50 under tension may be captured using a camera or the like. Based on an image obtained by the capturing, the position of the mask 50 in relation to the frame 41 is detected.

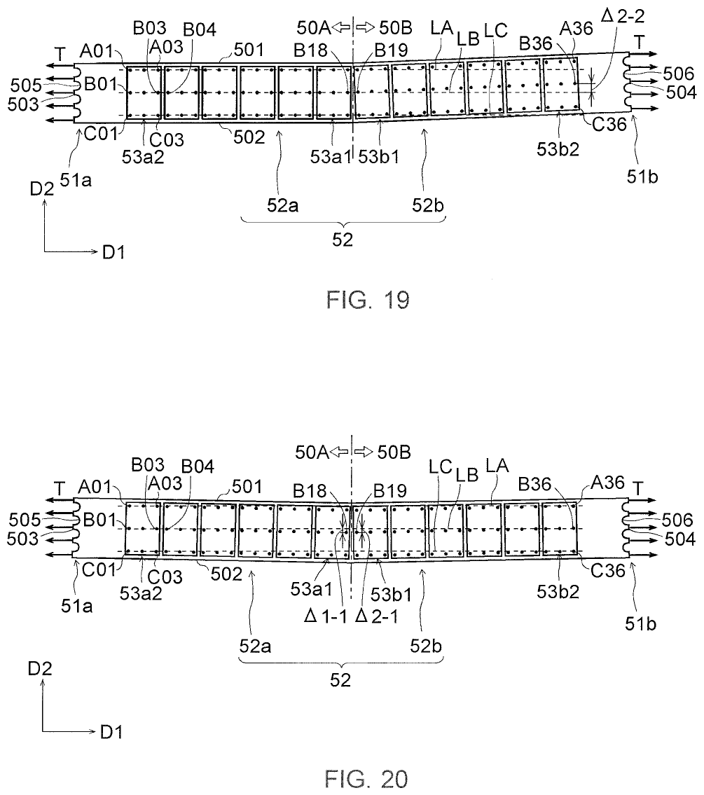

FIG. 19 is a plan view of an example of the mask 50 under tension T. The mask 50 may include a plurality of reference holes. The reference hole is used as an index to the position of the mask 50 in the alignment step. The reference hole may be the through hole 56 of the through-hole group 53. The position of the reference hole is detected based on an image obtained by capturing.

The plurality of reference holes may be provided at respective positions of the mask 50 in the first direction D1 and the second direction D2.

For example, the first portion 50A may include at least one first outer reference hole. The first outer reference hole(s) is a through hole of the first through-hole group located farthest from the second through-hole group 53b in the first direction D1. In the example illustrated in FIG. 19, the first through-hole group located farthest from the second through-hole group 53b in the first direction D1 is denoted as 53a2. In the example illustrated in FIG. 19, the through holes with the reference signs A01, B01, C01, etc. constitute the first outer reference holes.

For example, the first portion 50A may include at least one first inner reference hole. The first inner reference hole(s) is a through hole of the first through-hole group located next to the second through-hole group 53b in the first direction D1. In the example illustrated in FIG. 19, the first through-hole group located next to the second through-hole group 53b in the first direction D1 is denoted as 53a1. In the example illustrated in FIG. 19, the through hole with the reference sign B18, etc. constitute the first inner reference holes.

For example, the second portion 50B may include at least one second outer reference hole. The second outer reference hole(s) is a through hole of the second through-hole group located farthest from the first through-hole group 53a in the first direction D1. In the example illustrated in FIG. 19, the second through-hole group located farthest from the first through-hole group 53a in the first direction D1 is denoted as 53b2. In the example illustrated in FIG. 19, the through holes with the reference signs A36, B36, C36, etc. constitute the second outer reference holes.

For example, the second portion 50B may include at least one second inner reference hole. The second inner reference hole(s) is a through hole of the second through-hole group located next to the first through-hole group 53a in the first direction D1. In the example illustrated in FIG. 19, the second through-hole group located next to the first through-hole group 53a in the first direction D1 is denoted as 53b1. In the example illustrated in FIG. 19, the through hole with the reference sign B19, etc. constitute the second inner reference holes.

In the example illustrated in FIG. 19, the mask 50 includes reference holes A01 to A36, B01 to B36, and C01 to C36. The reference holes A01 to A36 are comprised of a part of the plurality of through holes 56, the part being arranged along the first side edge 501 from the first end 503 toward the second end 504. The reference holes C01 to C36 are comprised of a part of the plurality of through holes 56, the part being arranged along the second side edge 502 from the first end 503 toward the second end 504. The reference holes B01 to B36 are comprised of through holes 56 located at the middle row between the reference holes A01 to A36 and the reference holes C01 to C36 in the second direction D2.

The reference hole A01 is the through hole 56 belonging to the first through-hole group 53a2 and located closest to the first side edge 501 and closest to the first end 503. The reference hole C01 is the through hole 56 belonging to the first through-hole group 53a2 and located closest to the second side edge 502 and closest to the first end 503. The reference hole B01 is the through hole 56 located at the middle position between the reference hole A01 and the reference hole C01. The reference hole B18 is the through hole 56 belonging to the first through-hole group 53a1 and located closest to the second portion 50B and overlapping with the reference hole B01 when viewed in the first array direction.

The reference hole A36 is the through hole 56 belonging to the second through-hole group 53b2 and located closest to the first side edge 501 and closest to the second end 504. The reference hole C36 is the through hole 56 belonging to the second through-hole group 53b2 and located closest to the second side edge 502 and closest to the second end 504. The reference hole B36 is the through hole 56 located at the middle position between the reference hole A36 and the reference hole C36. The reference hole B19 is the through hole 56 belonging to the second through-hole group 53b1 and located closest to the first portion 50A and overlapping with the reference hole B36 when viewed in the second array direction.

In the example illustrated in FIG. 19, a reference line LA indicates ideal positions of the reference holes A01 to A36 in the second direction D2. A reference line LB indicates ideal positions of the reference holes B01 to B36 in the second direction D2. A reference line LC indicates ideal positions of the reference holes C01 to C36 in the second direction D2. The reference lines LA to LC are determined based on the reference ordinate system of the frame 41 and the designed positions of the through holes 56 of the mask 50.

In the present embodiment, as described above, the first array direction of the first through-hole group 53a is not in alignment with the second array direction of the second through-hole group 53b. In this case, when the tension T is applied to the mask 50, the deviation distance of the first outer reference hole or the second outer reference hole will increase. The deviation distance is the distance between the reference hole and the reference line in the second direction D2. In the example illustrated in FIG. 19, the deviation distance Δ2-2 of the reference hole A36, B36, C36 constituting the second outer reference hole is greater than each deviation distance of the other reference holes A01 to A35, B01 to B35, and C01 to C35. The alignment step may include an adjustment step in which the tension T applied to the mask 50 is adjusted. In the adjustment step, for example, the magnitude of the tension is adjusted. In the adjustment step, for example, the direction of the tension is adjusted. FIG. 20 is a plan view of an example of the mask 50 under adjusted tension T. In the example illustrated in FIG. 20, the tension T is adjusted such that, in the second direction D2, both the deviation distance of the first outer reference hole and the deviation distance of the second outer reference hole become less than or equal to a first adjustment threshold. The first adjustment threshold is, for example, 1.0 μm, or may be 0.5 μm, 0.3 μm, 0.2 μm, or 0.1 μm.

When the tension T is adjusted while focusing on the first outer reference hole and the second outer reference hole, each deviation distance of the first outer reference hole and the second outer reference hole becomes less than each deviation distance of the other reference holes. In this case, each deviation distance of the first inner reference hole and the second inner reference hole becomes greater than each deviation distance of the other reference holes. In the example illustrated in FIG. 20, the deviation distance Δ1-1 of the reference hole B18 constituting the first inner reference hole is greater than each deviation distance of the other reference holes B01 to B17, etc. located at the first portion 50A. In addition, the deviation distance Δ2-1 of the reference hole B19 constituting the second inner reference hole is greater than each deviation distance of the other reference holes B20 to B36, etc. located at the second portion 50B.

The alignment step may include a shift step of moving the mask 50 in the second direction D2. In the shift step, the mask 50 is moved in the second direction D2 such that all of the deviation distance of the first outer reference hole, the deviation distance of the first inner reference hole, and the deviation distance of the second outer reference hole become less than or equal to a second adjustment threshold. In the shift step, the mask 50 may be moved in the second direction D2 such that all of the deviation distance of the first outer reference hole, the deviation distance of the first inner reference hole, the deviation distance of the second inner reference hole, and the deviation distance of the second outer reference hole become less than or equal to a second adjustment threshold. The shift step may be executed after the adjustment step.

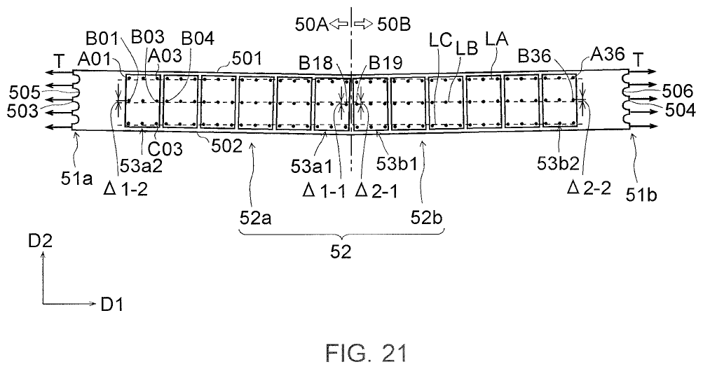

FIG. 21 is a plan view of an example of the mask 50 after the execution of the shift step. In the example illustrated in FIG. 21, in the shift step, the mask 50 is moved in the second direction D2 such that all of the deviation distance Δ1-2 of the first outer reference hole, the deviation distance Δ1-1 of the first inner reference hole, the deviation distance Δ2-1 of the second inner reference hole, and the deviation distance Δ2-2 of the second outer reference hole become less than or equal to the second adjustment threshold. This makes it possible to reduce the deviation distance of every reference hole on average. Therefore, it is possible to improve the PPA of an organic device manufactured using the mask 50. The second adjustment threshold is, for example, 5.0 μm, or may be 4.0 μm, 3.0 μm, 2.0 μm, or 1.0 μm. In the shift step, the mask 50 may be moved in the second direction D2 such that the difference between the deviation distance Δ1-2 of the first outer reference hole and the deviation distance Δ1-1 of the first inner reference hole becomes less than or equal to a third adjustment threshold. This makes it possible to achieve a greater reduction in the maximum value Amax of the deviation distances of all of the reference holes. The third adjustment threshold is, for example, 1.0 μm, or may be 0.5 μm, 0.3 μm, 0.2 μm, or 0.1 μm.

One embodiment described above can be modified in various ways. Another embodiment will be described below while referring to the drawings where necessary. In the description below, and in the drawings referred to in the description below, the same reference signs as those used for the corresponding portions in one embodiment described above will be used for portions that can be configured in the same manner as in one embodiment described above. Duplicative explanation will be omitted. When it is evident that working effects obtained in one embodiment described above can also be obtained in another embodiment, explanation thereof may be not given.

A second embodiment will now be described. In the foregoing embodiment, an example in which the borderline BL between the first portion 50A and the second portion 50B is determined based on the first step portion 501a, the distance G1, or the distance G3 has been disclosed. That is, an example in which the borderline BL is determined based on a deviation between the position of the first portion 50A and the position of the second portion 50B in the second direction D2 has been disclosed. In the second embodiment, an example in which the borderline BL is determined based on the center C1 of the mask 50 will be disclosed. The center C1 of the mask 50 is located at a midpoint between the borderline BL1 and the borderline BL2.

In a case where the center C1 is located between two through-hole groups 53 adjacent to each other in the first direction D1, the borderline BL may be determined as a straight line going through the center C1 and extending in the second direction D2. The two through-hole groups 53 adjacent to the center C1 are determined as the first through-hole group 53a1 and the second through-hole group 53b1.

In a case where the center C1 overlaps with one through-hole group 53 (referred to also as “central through-hole group 53”), the central through-hole group 53 is determined as the first through-hole group 53a1 or the second through-hole group 53b1. In a case where the second-nearest through-hole group 53, which is closest to the center C1 among those excluding the central through-hole group 53, is located on the first end 503 side with respect to the central through-hole group 53, this second-nearest through-hole group 53 is determined as the first through-hole group 53a1, and the central through-hole group 53 is determined as the second through-hole group 53b1. In a case where the second-nearest through-hole group 53, which is closest to the center C1 among those excluding the central through-hole group 53, is located on the second end 504 side with respect to the central through-hole group 53, this second-nearest through-hole group 53 is determined as the second through-hole group 53b1, and the central through-hole group 53 is determined as the first through-hole group 53a1.

### EXAMPLES

Next, embodiments of the present disclosure will now be explained in more detail by describing Examples; however, embodiments of the present disclosure shall not be construed to be limited to Examples described below unless they are beyond the gist thereof.

### Example 1

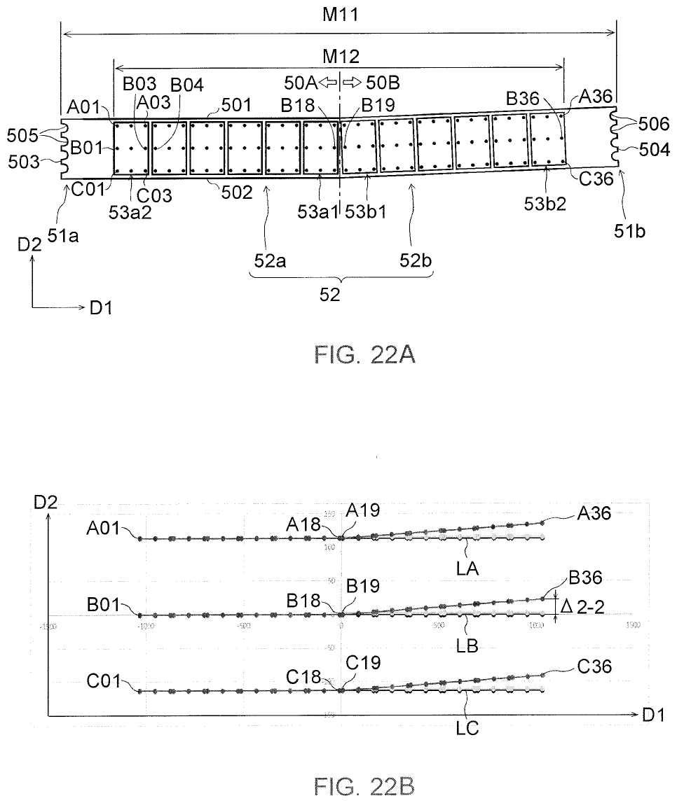

As illustrated in FIG. 22A, the mask 50 that includes the first portion 50A and the second portion 50B was designed. The design values of the dimensions of the mask 50 are as follows:
Dimension M11 of the mask 50 in the first direction D1: 2580 mm;
Dimension M12 of the middle portion 52 in the first direction D1: 2085 mm;
Dimension of the middle portion 52 in the second direction D2: 227 mm;
Dimension of the first end portion 51a in the second direction D2: 230 mm;
Dimension of the second end portion 51b in the second direction D2: 230 mm;
First angle: 0.00125°;
Dimension of the first step portion 501a in the second direction D2: 0.0 μm;
Thickness of the mask 50: 20 μm
The positions of the reference holes A01 to A36, B01 to B36, and C01 to C36 of the mask 50 in a state in which no tension is applied were calculated by running a simulation. The results are shown in FIG. 22B. The horizontal axis represents position in the first direction D1, and the vertical axis represents position in the second direction D2. The deviation distance of the first outer reference holes such as the reference hole B01 was 0.0 μm. The deviation distance of the second outer reference holes such as the reference hole B36 was 22.5 μm.

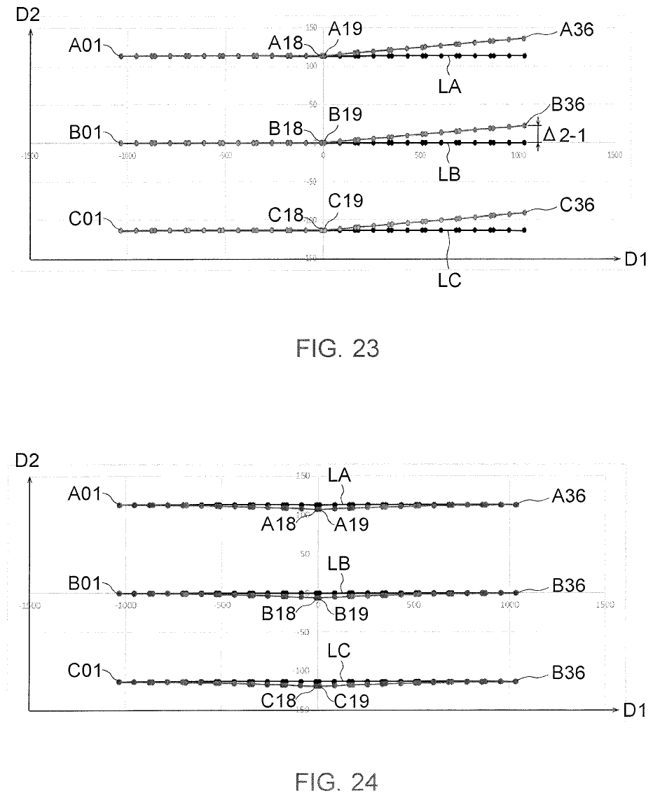

Next, the positions of the reference holes A01 to A36, B01 to B36, and C01 to C36 of the mask 50 in a state in which tension of 25 N is applied were calculated by running a simulation. The results are shown in FIG. 23. The deviation distance of the second outer reference holes such as the reference hole B36 was 22.6 μm.

Next, the adjustment step of adjusting the tension in such a way as to bring the positions of the first outer reference holes and the positions of the second outer reference holes into alignment with each other was executed by running a simulation. In addition, the positions of the reference holes A01 to A36, B01 to B36, and C01 to C36 after the adjustment step were calculated by running a simulation. The results are shown in FIG. 24. Both the deviation distance of the first outer reference holes and the deviation distance of the second outer reference holes were 0.0 Both the deviation distance of the first inner reference holes and the deviation distance of the second inner reference holes were 6.0 μm.

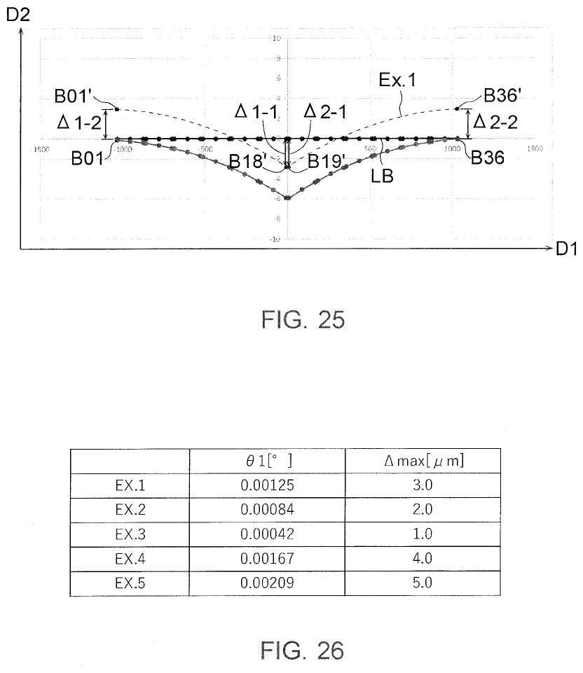

Next, the shift step of moving the mask 50 in the second direction D2 was executed by running a simulation. In addition, the positions of the reference holes B01 to B36 after the shift step were calculated by running a simulation. The results are shown in FIG. 25. In FIG. 25, reference holes after the execution of the shift step are denoted as B01′ to B36′. All of the deviation distance Δ1-2 of the first outer reference hole, the deviation distance M-1 of the first inner reference hole, the deviation distance Δ2-1 of the second inner reference hole, and the deviation distance Δ2-2 of the second outer reference hole were 3.0 μm. Therefore, as illustrated in FIG. 26, the maximum value Amax of the deviation distances of all of the reference holes was 3.0 μm.

### Example 2

The mask 50 including the first portion 50A and the second portion 50B was designed, similarly to Example 1 except for the difference that the first angle was designed to be 0.00084°. Next, similarly to Example 1, the positions of the reference holes B01 to B36 after the execution of the adjustment step and the shift step were calculated by running a simulation. As illustrated in FIG. 26, the maximum value Amax of the deviation distances of all of the reference holes was 2.0 μm.

### Example 3

The mask 50 including the first portion 50A and the second portion 50B was designed, similarly to Example 1 except for the difference that the first angle was designed to be 0.00042°. Next, similarly to Example 1, the positions of the reference holes B01 to B36 after the execution of the adjustment step and the shift step were calculated by running a simulation. As illustrated in FIG. 26, the maximum value Amax of the deviation distances of all of the reference holes was 1.0 μm.

### Example 4

The mask 50 including the first portion 50A and the second portion 50B was designed, similarly to Example 1 except for the difference that the first angle was designed to be 0.00167°. Next, similarly to Example 1, the positions of the reference holes B01 to B36 after the execution of the adjustment step and the shift step were calculated by running a simulation. As illustrated in FIG. 26, the maximum value Amax of the deviation distances of all of the reference holes was 4.0 μm.

### Example 5

The mask 50 including the first portion 50A and the second portion 50B was designed, similarly to Example 1 except for the difference that the first angle was designed to be 0.00209°. Next, similarly to Example 1, the positions of the reference holes B01 to B36 after the execution of the adjustment step and the shift step were calculated by running a simulation. As illustrated in FIG. 26, the maximum value Amax of the deviation distances of all of the reference holes was 5.0 μm.

The inclination of the maximum value Amax with respect to the first angle θ1, calculated based on Examples 1 to 5, is 4820[μm/° ].

1. A method of manufacturing a mask, the mask including a first portion and a second portion, the first portion including at least one first through-hole group, the second portion including at least one second through-hole group located next to the first through-hole group in a first direction, the method comprising:
a step of preparing a laminated body that includes an original base material and a resist layer;
a first exposure process of exposing the resist layer corresponding to the first portion by using a first exposure mask;
a second exposure process of exposing the resist layer corresponding to the second portion by using a second exposure mask;
a process of developing the resist layer corresponding to the first portion and the resist layer corresponding to the second portion; and
a process of etching the original base material through the resist layer corresponding to the first portion and the resist layer corresponding to the second portion, wherein
the first exposure mask includes a first surface first exposure mask, through which the resist layer located on a first surface of the original base material is exposed, and a second surface first exposure mask, through which the resist layer located on a second surface of the original base material is exposed,
in the first exposure process, the resist layer located on the first surface is exposed using the first surface first exposure mask, and the resist layer located on the second surface is exposed using the second surface first exposure mask,
the second exposure mask includes a first surface second exposure mask, through which the resist layer located on the first surface is exposed, and a second surface second exposure mask, through which the resist layer located on the second surface is exposed,
in the second exposure process, the resist layer located on the first surface is exposed using the first surface second exposure mask, and the resist layer located on the second surface is exposed using the second surface second exposure mask,
a peripheral edge of the first portion and the first through-hole group are formed through the original base material by etching through the resist layer corresponding to the first portion, and
a peripheral edge of the second portion and the second through-hole group are formed through the original base material by etching through the resist layer corresponding to the second portion.

2. The method according to claim 1, wherein
the first exposure mask has a quadrangular shape that includes a first side and a second side,
the first side has a length of 1090 mm or greater, and
the second side has a length of 810 mm or greater.

3. The method according to claim 1, wherein
a thickness of the original base material is 30 μm or greater.

4. The method according to claim 1, wherein
the second exposure process includes a process of adjusting a position of the second exposure mask while taking, as a reference, the resist layer corresponding to the first portion after execution of the first exposure process.

5. The method according to claim 1, wherein
the second exposure process includes a process of adjusting a position of the second exposure mask while taking, as a reference, a position of the first exposure mask having been used in the first exposure process.

6. The method according to claim 1, wherein
the first exposure process includes a process of performing a relative position adjustment between the first surface first exposure mask and the second surface first exposure mask, and
the second exposure process includes a process of performing a relative position adjustment between the first surface second exposure mask and the second surface second exposure mask.

7. A mask, comprising:
a base material that includes a first side edge and a second side edge extending in a first direction and that includes a first surface and a second surface; and
a plurality of through-hole groups going through the base material, wherein
in a plan view, the mask includes a first portion and a second portion, the first portion including at least one first through-hole group among the through-hole groups, the second portion including, among the through-hole groups, at least one second through-hole group located next to the first through-hole group in the first direction,
a first angle θ1 formed by a first array direction of the first through-hole group and a second array direction of the second through-hole group is 0.00042° or greater,
the first array direction is an array direction of through holes belonging to the first through-hole group and arranged along the first side edge, and
the second array direction is an array direction of through holes belonging to the second through-hole group and arranged along the first side edge.

8. The mask according to claim 7, wherein
in a plan view, the mask includes a middle portion that includes the plurality of through-hole groups arranged in the first direction, and
a dimension of the middle portion in the first direction is 1000 mm or greater and 2200 mm or less.

9. The mask according to claim 7, wherein
the first side edge includes a first step portion located at a boundary between the first portion and the second portion and displaced in a second direction orthogonal to the first direction.

10. The mask according to claim 9, wherein
a dimension S1 of the first step portion is 3.0 μm or less.

11. The mask according to claim 10, wherein
the first angle θ1 is 0.00125° or less.

12. The mask according to claim 9, wherein
a formula of 4820[μm/°]×θ1[°]+S1[μm]≤6.0[μm] holds between the dimension S1 of the first step portion and the first angle θ1.

13. The mask according to claim 7, wherein
a dimension of the first portion in the first direction is 900 mm or greater, and
a dimension of the second portion in the first direction is 900 mm or greater.

14. The mask according to claim 7, wherein
the first portion includes a first end that is an end of the mask in the first direction, and
the second portion includes a second end that is an end of the mask in the first direction.

15. The mask according to claim 14, wherein
in a plan view, each of the first end and the second end includes two or more recesses arranged in a second direction orthogonal to the first direction.

16. The mask according to claim 15, wherein
the recess has a dimension of 5 mm or greater in the first direction.

17. A method of manufacturing a mask apparatus, comprising:
an alignment step of determining a position of the mask in relation to a frame while applying tension to the mask according to claim 7; and
a fixing step of fixing the mask to the frame, wherein
the first portion includes a first inner reference hole that is a through hole of the first through-hole group located next to the second through-hole group in the first direction and a first outer reference hole that is a through hole of, among the through-hole groups, a first through-hole group located farthest from the second through-hole group in the first direction,
the second portion includes a second outer reference hole that is a through hole of, among the through-hole groups, a second through-hole group located farthest from the first through-hole group in the first direction, and
the alignment step includes an adjustment step and a shift step, the adjustment step being a step of adjusting the tension on a basis of the first outer reference hole and the second outer reference hole, and the shift step being a step of moving the mask in a second direction orthogonal to the first direction after the adjustment step on a basis of the first inner reference hole.

18. The method according to claim 17, wherein
in the adjustment step, the tension is adjusted such that, in the second direction, both a deviation distance of the first outer reference hole and a deviation distance of the second outer reference hole become less than or equal to a first adjustment threshold.

19. The method according to claim 18, wherein
in the shift step, the mask is moved in the second direction such that, in the second direction, all of the deviation distance of the first outer reference hole, a deviation distance of the first inner reference hole, and the deviation distance of the second outer reference hole become less than or equal to a second adjustment threshold.

20. The method according to claim 19, wherein
in the shift step, the mask is moved in the second direction such that a difference between the deviation distance of the first outer reference hole and the deviation distance of the first inner reference hole becomes less than or equal to a third adjustment threshold.

21. The method according to claim 17, wherein
a dimension of the frame in the second direction is 1200 mm or greater.
